(19) United States
(12) Patent Application Publication
(10) Pub. No.: US 2014/0287597 A1
(43) Pub. Date: Sep. 25, 2014

(54) METHOD OF MANUFACTURING SEMICONDUCTOR DEVICE, SUBSTRATE PROCESSING APPARATUS, AND RECORDING MEDIUM

(71) Applicant: HITACHI KOKUSAI ELECTRIC INC., Tokyo (JP)

(72) Inventors: Yoshiro HIROSE, Toyama-shi (JP); Ryuji YAMAMOTO, Kodaira-shi (JP); Atsushi SANO, Toyama-shi (JP)

(73) Assignee: HITACHI KOKUSAI ELECTRIC INC., Tokyo (JP)

(21) Appl. No.: 14/219,414

(22) Filed: Mar. 19, 2014

(30) Foreign Application Priority Data
Mar. 19, 2013 (JP) 2013-057192

(51) Int. Cl. H01L 21/02

(52) U.S. Cl. CPC H01L 21/02172; H01L 21/02205
USPC 438/786; 118/706

(57) ABSTRACT

A method of manufacturing a semiconductor device includes forming a thin film containing a predetermined element, boron, carbon, and nitrogen and having a borazine ring skeleton on a substrate by performing a cycle a predetermined number of times. The cycle includes supplying a first precursor gas containing the predetermined element and a halogen group to the substrate; supplying a second precursor gas containing the predetermined element and an amino group to the substrate; supplying a reaction gas including an organic borazine compound to the substrate; and supplying a carbon-containing gas to the substrate. In addition, the cycle is performed under a condition in which the borazine ring skeleton in the organic borazine compound is maintained.

### CROSS-REFERENCE TO RELATED APPLICATION

This application is based upon and claims the benefit of priority from Japanese Patent Application No. 2013-057192, filed on Mar. 19, 2013, the entire contents of which are incorporated herein by reference.

### TECHNICAL FIELD

The present disclosure relates to a method of manufacturing a semiconductor device which includes a process of forming a thin film on a substrate, a substrate processing apparatus, and a recording medium.

### BACKGROUND

As sizes of transistors decrease, a thin film such as an insulating film which constitutes a sidewall spacer (SWS) of a gate electrode or the like may require a low temperature for film forming, an improved resistance to hydrogen fluoride (HF), and a small dielectric constant. To this end, it has been studied to use a silicon borocarbonitride (SiBCN) film obtained by adding boron (B) and carbon (C) to a silicon nitride film (SiN film) as an insulating film.

Such an insulating film is often formed by an alternating supply method that alternately supplies several kinds of process gases because high step coverage characteristics are required. For example, using a silicon (Si)-containing gas as a precursor gas (i.e., a silicon precursor), a boron trichloride (BCl₃) gas or a diborane (B₂H₆) gas as a boron precursor, an ammonia (NH₃) gas as a nitrogen source, and an ethylene (C₂H₄) gas or a propylene (C₃H₆) gas as a carbon source, a SiBCN film can be formed on a substrate by performing a predetermined number of times a cycle that sequentially supplies those process gases to the substrate. However, the method that separately supplies the silicon precursor, the boron precursor, the nitrogen source, and the carbon source leads to a longer time for performing a single cycle, which results in a low productivity of a film forming process. Furthermore, in the method as described above, it is difficult to increase a C concentration in the SiBCN film and thus improve the resistance to HF.

### SUMMARY

According to some embodiments of the present disclosure, it is possible to form a thin film having a high resistance to HF and a low dielectric constant in a low temperature range, with high productivity.

According to some embodiments of the present disclosure, there is provided a method of manufacturing a semiconductor device, including: forming a thin film containing a predetermined element, boron, carbon, and nitrogen and having a borazine ring skeleton on a substrate, by performing a cycle a predetermined number of times, the cycle including: supplying a first precursor gas containing the predetermined element and a halogen group to the substrate; supplying a second precursor gas containing the predetermined element and an amino group to the substrate; supplying a reaction gas including an organic borazine compound to the substrate; and supplying a carbon-containing gas to the substrate, wherein the cycle is performed under a condition in which the borazine ring skeleton in the organic borazine compound is maintained.

According to some other embodiments of the present disclosure, there is provided a substrate processing apparatus, including: a process chamber configured to accommodate a substrate; a first precursor gas supply system configured to supply a first precursor gas containing a predetermined element and a halogen group into the process chamber; a second precursor gas supply system configured to supply a second precursor gas containing the predetermined element and an amino group into the process chamber; a reaction gas supply system configured to supply a reaction gas including an organic borazine compound into the process chamber; a carbon-containing gas supply system configured to supply a carbon-containing gas into the process chamber; a heater configured to heat the substrate in the process chamber; a pressure adjusting part configured to adjust a pressure in the process chamber; and a control part configured to control the first precursor gas supply system, the second precursor gas supply system, the reaction gas supply system, the carbon-containing gas supply system, the heater, and the pressure adjusting part so as to form a thin film containing the predetermined element, boron, carbon, and nitrogen and having a borazine ring skeleton on the substrate, by performing a cycle a predetermined number of times, the cycle including: supplying the first precursor gas to the substrate in the process chamber; supplying the second precursor gas to the substrate in the process chamber; supplying the reaction gas to the substrate in the process chamber; and supplying the carbon-containing gas to the substrate in the process chamber, wherein the cycle is performed under a condition in which the borazine ring skeleton in the organic borazine compound is maintained.

According to yet other embodiments of the present disclosure, there is provided a non-transitory computer-readable medium storing a program that causes a computer to perform a process of forming a thin film containing a predetermined element, boron, carbon, and nitrogen and having a borazine ring skeleton on a substrate in a process chamber of a substrate processing apparatus, by performing a cycle a predetermined number of times, the cycle including: supplying a first precursor gas containing the predetermined element and a halogen group to the substrate in the process chamber; supplying a second precursor gas containing the predetermined element and an amino group to the substrate in the process chamber; supplying a reaction gas including an organic borazine compound to the substrate in the process chamber; and supplying a carbon-containing gas to the substrate in the process chamber, wherein the cycle is performed under a condition in which the borazine ring skeleton in the organic borazine compound is maintained.

### BRIEF DESCRIPTION OF THE DRAWINGS

FIG. 1 is a schematic configuration view of a vertical processing furnace of a substrate processing apparatus suitably used in some embodiments of the present disclosure, in which a portion of the processing furnace is shown in a longitudinal cross-sectional view.

FIG. 2 is a schematic configuration view of the vertical processing furnace of the substrate processing apparatus suitably used in some embodiments of the present disclosure, in which a portion of the processing furnace is shown in a cross-sectional view taken along line A-A in FIG. 1.

FIG. 3 is a schematic configuration view of a controller of the substrate processing apparatus suitably used in some embodiments of the present disclosure, in which a control system of the controller is shown by a block diagram.

FIG. 4 is a view showing a film-forming flow in a first sequence of a first embodiment of the present disclosure.

FIG. 5 is a view showing a film-forming flow in a second sequence of the first embodiment of the present disclosure.

FIG. 6 is a view showing gas supply timing in the first sequence of the first embodiment of the present disclosure.

FIG. 7 is a view showing gas supply timing in the second sequence of the first embodiment of the present disclosure.

FIG. 8 is a view showing a film-forming flow in a first sequence of a second embodiment of the present disclosure.

FIG. 9 is a view showing a film-forming flow in a second sequence of the second embodiment of the present disclosure.

FIGS. 10A and 10B are views showing timings of gas supply and plasma power supply in the first sequence of the second embodiment of the present disclosure, FIG. 10A showing an example of a film-forming sequence under non-plasma condition and FIG. 10B showing an example of a film-forming sequence using plasma.

FIGS. 11A and 11B are views showing timings of gas supply and plasma power supply in the second sequence of the second embodiment of the present disclosure, FIG. 11A showing an example of a film-forming sequence under non-plasma condition and FIG. 11B showing an example of a film-forming sequence using plasma.

FIG. 12A shows a chemical structural formula of borazine. FIG. 12B shows a chemical structural formula of a borazine compound, FIG. 12C showing a chemical structural formula of n,n′,n″-trimethyl borazine and FIG. 12D showing a chemical structural formula of n,n′,n″-tri-n-propyl borazine.

FIG. 13 is a view showing gas supply timing of a carbon-containing gas in a film-forming sequence in some embodiments of the present disclosure and its modifications.

### DETAILED DESCRIPTION

### First Embodiment of the Present Disclosure

Hereinafter, a first embodiment of the present disclosure will now be described with reference to the drawings.

### (1) Configuration of Substrate Processing Apparatus

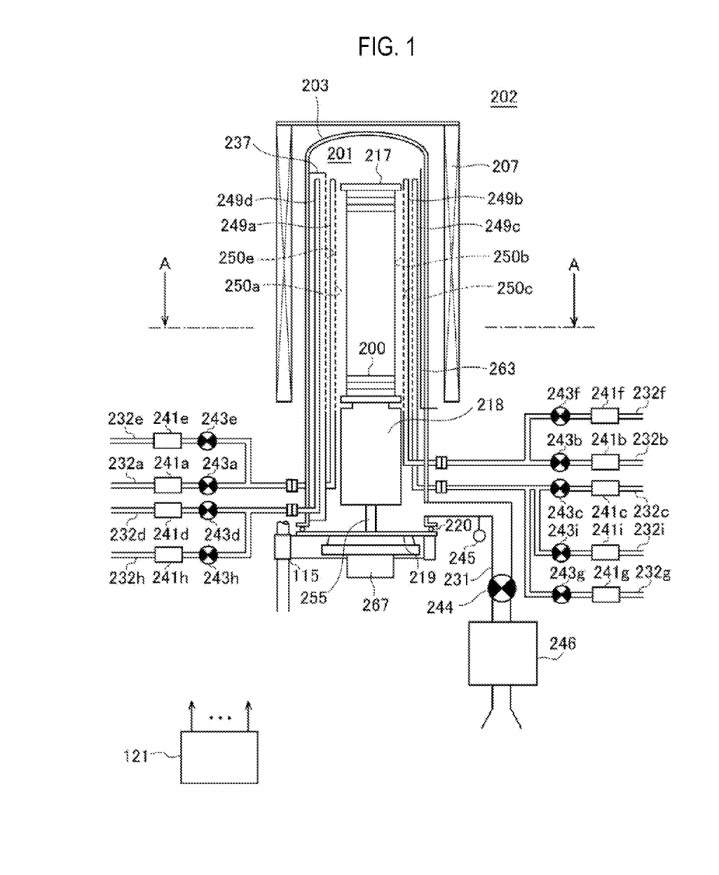

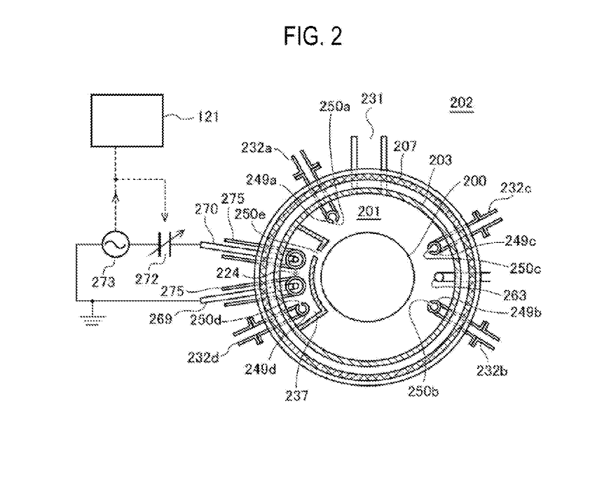

FIG. 1 is a schematic configuration view of a vertical processing furnace 202 of a substrate processing apparatus suitably used in some embodiments, in which a portion of the processing furnace 202 is shown in a longitudinal cross-sectional view. FIG. 2 is a schematic configuration view of the vertical processing furnace 202 suitably used in some embodiments, in which a portion of the processing furnace 202 is shown in a cross-sectional view taken along line A-A in FIG. 1.

As shown in FIG. 1, the processing furnace 202 includes a heater 207 as a heating unit (a heating mechanism). The heater 207 has a cylindrical shape and is supported by a heater base (not shown) serving as a support plate so as to be vertically installed. In addition, the heater 207 functions as an activation mechanism (an excitation unit) configured to thermally activate (excite) a gas, as described later.

A reaction tube 203 forming a reaction vessel (process vessel) is disposed inside the heater 207 in a concentric form along the heater 207. The reaction tube 203 is made of a heat resistant material such as quartz (SiO₂) or silicon carbide (SiC) and has a cylindrical shape with its upper end closed and its lower end opened. A process chamber 201 is formed in a hollow cylindrical portion of the reaction tube 203. The process chamber 201 is configured to accommodate a plurality of wafers 200 as substrates. The wafers 200 are horizontally stacked in multiple stages along a vertical direction in a boat 217 which will be described later.

A first nozzle 249a, a second nozzle 249b, a third nozzle 249c and a fourth nozzle 249d are installed in the process chamber 201 to penetrate through a lower portion of the reaction tube 203. The first nozzle 249a, the second nozzle 249b, the third nozzle 249c and the fourth nozzle 249d are respectively connected to a first gas supply pipe 232a, a second gas supply pipe 232b, a third gas supply pipe 232c and a fourth gas supply pipe 232d. The third gas supply pipe 232c is connected to a fifth gas supply pipe 232i. In this way, the four nozzles 249a to 249d and the five gas supply pipes 232a to 232i are installed in the reaction tube 203 to supply plural types of gases, in this example, five kinds of gases, into the process chamber 201.

Moreover, a manifold made of metal and configured to support the reaction tube 203 may be installed under the reaction tube 203, and each of the nozzles may be installed to penetrate through a sidewall of the metal manifold. In this case, an exhaust pipe 231 described later may be installed at the metal manifold. In addition, even in this case, the exhaust pipe 231 may be installed at a lower portion of the reaction tube 203 rather than at the metal manifold. A furnace port of the processing furnace 202 may be formed of metal, and the nozzle or the like may be installed at the metal furnace port.

A mass flow controller (MFC) 241a, which is a flow rate controller (a flow rate control part), and a valve 243a, which is an opening/closing valve, are installed in the first gas supply pipe 232a in this order from an upstream direction. In addition, a first inert gas supply pipe 232e is connected to the first gas supply pipe 232a at a downstream side of the valve 243a. An MFC 241e, which is a flow rate controller (a flow rate control part), and a valve 243e, which is an opening/closing valve, are installed at the first inert gas supply pipe 232e in this order from an upstream direction. In addition, the above-described first nozzle 249a is connected to a leading end portion of the first gas supply pipe 232a. The first nozzle 249a is installed in an arc-shaped space between an inner wall of the reaction tube 203 and the wafers 200. The first nozzle 249a is vertically disposed along an inner wall of the reaction tube 203 to rise upward in a stacking direction of the wafers 200. That is, the first nozzle 249a is installed in a flank of a wafer arrangement region, in which the wafers 200 are arranged. The first nozzle 249a is configured as an L-shaped long nozzle and has its horizontal portion installed to penetrate through a lower sidewall of the reaction tube 203 and its vertical portion installed to rise from one end portion of the wafer arrangement region toward the other end portion thereof. A plurality of gas supply holes 250a through which gas is supplied is formed at a side surface of the first nozzle 249a. The gas supply holes 250a are opened toward a center of the reaction tube 203 so that the gas can be supplied toward the wafers 200. The plurality of gas supply holes 250a is disposed at a predetermined opening pitch from a lower portion to an upper portion of the reaction tube 203. Each of the plurality of gas supply holes 250a has the same opening area.

A first gas supply system is mainly configured by the first gas supply pipe 232a, the MFC 241a and the valve 243a. In addition, the first nozzle 249a may be included in the first gas supply system. Further, a first inert gas supply system is mainly configured by the first inert gas supply pipe 232e, the MFC 241e and the valve 243e. The first inert gas supply system may also function as a purge gas supply system.

An MFC 241b, which is a flow rate controller (a flow rate control part), and a valve 243b, which is an opening/closing valve, are installed in the second gas supply pipe 232b in this order from an upstream direction. In addition, a second inert gas supply pipe 232f is connected to the second gas supply pipe 232b at a downstream side of the valve 243b. An MFC 241f, which is a flow rate controller (a flow rate control part), and a valve 243f, which is an opening/closing valve, are installed at the second inert gas supply pipe 232f in this order from an upstream direction. In addition, the above-described second nozzle 249b is connected to a leading end portion of the second gas supply pipe 232b. The second nozzle 249b is installed in an arc-shaped space between the inner wall of the reaction tube 203 and the wafers 200. The second nozzle 249b is vertically disposed along the inner wall of the reaction tube 203 to rise upward in the stacking direction of the wafers 200. That is, the second nozzle 249b is installed in the flank of the wafer arrangement region, in which the wafers 200 are arranged. The second nozzle 249b is configured as an L-shaped long nozzle and has its horizontal portion installed to penetrate through the lower sidewall of the reaction tube 203 and its vertical portion installed to rise from one end portion of the wafer arrangement region toward the other end portion thereof. A plurality of gas supply holes 250b through which the gas is supplied is formed at a side surface of the second nozzle 249b. The gas supply holes 250b are opened toward the center of the reaction tube 203 so that the gas can be supplied toward the wafer 200. The plurality of gas supply holes 250b is disposed at a predetermined opening pitch from a lower portion to an upper portion of the reaction tube 203. Each of the plurality of gas supply holes 250b has the same opening area.

A second gas supply system is mainly configured by the second gas supply pipe 232b, the MFC 241b and the valve 243b. In addition, the second nozzle 249b may be included in the second gas supply system. Further, a second inert gas supply system is mainly configured by the second inert gas supply pipe 232f, the MFC 241f and the valve 243f. The second inert gas supply system may also function as a purge gas supply system.

An MFC 241c, which is a flow rate controller (a flow rate control part), and a valve 243c, which is an opening/closing valve, are installed in the third gas supply pipe 232c in this order from an upstream direction. In addition, a fifth gas supply pipe 232i is connected to the third gas supply pipe 232c at a downstream side of the valve 243c. An MFC 241i, which is a flow rate controller (a flow rate control part), and a valve 243i, which is an opening/closing valve, are installed in the fifth gas supply pipe 232i in this order from an upstream direction. Further, a third inert gas supply pipe 232g is connected to the third gas supply pipe 232c at a downstream side of a connecting position of the fifth gas supply pipe 232i and the third gas supply pipe 232c. An MFC 241g, which is a flow rate controller (a flow rate control part), and a valve 243g, which is an opening/closing valve, are installed at the third inert gas supply pipe 232g in this order from an upstream direction. In addition, the above-described third nozzle 249c is connected to a leading end portion of the third gas supply pipe 232c. The third nozzle 249c is installed in the arc-shaped space between the inner wall of the reaction tube 203 and the wafers 200. The third nozzle 249c is vertically disposed along the inner wall of the reaction tube 203 to rise upward in the stacking direction of the wafers 200. That is, the third nozzle 249c is installed in the flank of the wafer arrangement region, in which the wafers 200 are arranged. The third nozzle 249c is configured as an L-shaped long nozzle and has its horizontal portion installed to penetrate through the lower sidewall of the reaction tube 203 and its vertical portion installed to rise from at least one end portion of the wafer arrangement region toward the other end portion thereof. A plurality of gas supply holes 250c through which gas is supplied is formed at a side surface of the third nozzle 249c. The gas supply holes 250c are opened toward the center of the reaction tube 203 so that the gas can be supplied toward the wafers 200. The plurality of gas supply holes 250c is disposed at a predetermined opening pitch from a lower portion to an upper portion of the reaction tube 203. Each of the plurality of gas supply holes 250c has the same opening area.

A third gas supply system is mainly configured by the third gas supply pipe 232c, the MFC 241c and the valve 243c. In addition, the third nozzle 249c may be included in the third gas supply system. Further, a fifth gas supply system is mainly configured by the fifth gas supply pipe 232i, the MFC 241i and the valve 243i. In addition, the third nozzle 249c disposed at a downstream side of a connecting position of the third gas supply pipe 232c and the fifth gas supply pipe 232i may be included in the fifth gas supply system. In addition, a third inert gas supply system is mainly configured by the third inert gas supply pipe 232g, the MFC 241g and the valve 243g. The third inert gas supply system may also function as a purge gas supply system.

An MFC 241d, which is a flow rate controller (a flow rate control part), and a valve 243d, which is an opening/closing valve, are installed in the fourth gas supply pipe 232d in this order from an upstream direction. In addition, a fourth inert gas supply pipe 232h is connected to the fourth gas supply pipe 232d at a downstream side of the valve 243d. An MFC 241h, which is a flow rate controller (a flow rate control part), and a valve 243h, which is an opening/closing valve, are installed at the fourth inert gas supply pipe 232h in this order from an upstream direction. In addition, the above-described fourth nozzle 249d is connected to a leading end portion of the fourth gas supply pipe 232d. The fourth nozzle 249d is installed inside a buffer chamber 237 that is a gas diffusion space.

The buffer chamber 237 is installed in an arc-shaped space between the inner wall of the reaction tube 203 and the wafers 200. The buffer chamber 237 is vertically disposed along the inner wall of the reaction tube 203 to rise upward in the stacking direction of the wafers 200. That is, the buffer chamber 237 is installed in the flank of the wafer arrangement region, in which the wafers 200 are arranged. A plurality of gas supply holes 250e through which gas is supplied is formed at an end portion of a wall of the buffer chamber 237 adjacent to the wafers 200. The gas supply holes 250e are opened toward the center of the reaction tube 203 so that the gas can be supplied toward the wafer 200. The plurality of gas supply holes 250e is disposed at a predetermined opening pitch from a lower portion to an upper portion of the reaction tube 203. Each of the plurality of gas supply holes 250e has the same opening area.

The fourth nozzle 249d is installed along the inner wall of the reaction tube 203 to rise upward in the stacking direction of the wafers 200 in an end portion of the buffer chamber 237 opposite to the end portion thereof in which the gas supply holes 250e are formed. That is, the fourth nozzle 249d is installed in the flank of the wafer arrangement region, in which the wafers 200 are arranged. The fourth nozzle 249d is configured as an L-shaped long nozzle and has its horizontal portion installed to penetrate through the lower sidewall of the reaction tube 203 and its vertical portion installed to rise from one end portion of the wafer arrangement region toward the other end portion thereof. A plurality of gas supply holes 250d through which gas is supplied is formed at a side surface of the fourth nozzle 249d. The gas supply holes 250d are opened toward the center of the buffer chamber 237. The plurality of gas supply holes 250e are disposed from the lower portion to the upper portion of the reaction tube 203 in the same way as the gas supply holes 250e of the buffer chamber 237. When a pressure difference between an interior of the buffer chamber 237 and an interior of the process chamber 201 is small, the plurality of the gas supply holes 250d may be configured to have a constant opening area and a constant opening pitch from an upstream side (i.e., a lower portion) to a downstream side (i.e., an upper portion). In contrast, when the pressure difference is large, the opening area may become larger and the opening pitch may become smaller in a direction from the upstream side to the downstream side.

In some embodiments, by adjusting the opening area or opening pitch of each gas supply hole 250d of the fourth nozzle 249d from the upstream side to the downstream side as described above, gases may be ejected at an almost same flow rate from the respective gas supply holes 250d despite a flow velocity difference. The gas flown out from the individual gas supply holes 250d is introduced into the buffer chamber 237 and the flow velocity of the gas becomes uniform within the buffer chamber 237. In this case, particle velocity of the gases ejected from the respective gas supply holes 250d of the fourth nozzle 249d into the buffer chamber 237 are reduced in the buffer chamber 237, and then are ejected from the respective gas supply holes 250e of the buffer chamber 237 into the process chamber 201. Thereby, the gases ejected from the respective gas supply holes 250d of the fourth nozzle 249d into the buffer chamber 237 have a uniform flow rate and flow velocity when the gases are ejected from the respective gas supply holes 250e of the buffer chamber 237 into the process chamber 201.

A fourth gas supply system is mainly configured by the fourth gas supply pipe 232d, the MFC 241d and the valve 243d. In addition, the fourth nozzle 249d and the buffer chamber 237 may be included in the fourth gas supply system. Further, a fourth inert gas supply system is mainly configured by the fourth inert gas supply pipe 232h, the MFC 241h and the valve 243h. The fourth inert gas supply system may also function as a purge gas supply system.

As described above, in the method of supplying gas according to some embodiments, the gas may be transferred through the nozzles 249a to 249d and the buffer chamber 237 disposed in an arc-shaped longitudinal long space defined by the inner wall of the reaction tube 203 and end portions of the stacked wafers 200. The gas is first ejected into the reaction tube 203 near the wafers 200 through the gas supply holes 250a to 250e opened in the nozzles 249a to 249d and the buffer chamber 237, respectively. Thus, a main flow of the gas in the reaction tube 203 follows a direction parallel to surfaces of the wafers 200, i.e., a horizontal direction. With this configuration, the gas can be uniformly supplied to the respective wafers 200, and therefore, a film thickness of a thin film formed on each of the wafers 200 can be uniform. In addition, a gas flowing on the surface of the wafer 200 after reaction, i.e., a residual gas, flows toward an exhaust port, i.e., the exhaust pipe 231. The flow direction of the residual gas may be appropriately decided depending on a position of the exhaust port, and is not limited to a vertical direction.

A first precursor gas containing a predetermined element and a halogen group, for example, a chlorosilane-based precursor gas as a first precursor gas containing at least silicon (Si) and a chloro group, is supplied into the process chamber 201 via the MFC 241a, the valve 243a and the first nozzle 249a from the first gas supply pipe 232a. Here, the chlorosilane-based precursor gas refers to a chlorosilane-based precursor in a gaseous state, for example, a gas obtained by evaporating a chlorosilane-based precursor in a liquid state under normal temperature (e.g., room temperature) and normal pressure, or a chlorosilane-based precursor in a gaseous state under normal temperature and pressure. In addition, the chlorosilane-based precursor refers to a silane-based precursor containing a chloro group as a halogen group, and a precursor containing at least silicon (Si) and chlorine (Cl). That is, here, the chlorosilane-based precursor may refer to a kind of halide. In addition, the term “precursor” used in the description may refer to “a liquid precursor in a liquid state,” “a precursor gas in a gaseous state,” or both of them. Accordingly, the term “chlorosilane-based precursor” used in the description may refer to “a chlorosilane-based precursor in a liquid state,” “a chlorosilane-based precursor gas in a gaseous state,” or both of them. For example, hexachlorodisilane (Si₂Cl₆, abbreviation: HCDS) may be used as the chlorosilane-based precursor. In addition, when a liquid precursor in the liquid state under normal temperature and pressure, such as the HCDS, is used, the liquid precursor is evaporated by an evaporation system such as an evaporator, a bubbler, or the like, and is supplied as a precursor gas (HCDS gas).

A second precursor gas containing a predetermined element and an amino group (amine group), for example, an aminosilane-based precursor gas as a second precursor gas containing at least silicon (Si) and the amino group, is supplied into the process chamber 201 via the MFC 241b, the valve 243b and the second nozzle 249b from the second gas supply pipe 232b. Here, the aminosilane-based precursor gas refers to an aminosilane-based precursor in a gaseous state, for example, a gas obtained by evaporating an aminosilane-based precursor in a liquid state under normal temperature and pressure, or an aminosilane-based precursor in a gaseous state under normal temperature and pressure. In addition, the aminosilane-based precursor refers to a silane-based precursor having an amino group (which may also be a silane-based precursor containing an alkyl group such as a methyl group, ethyl group or butyl group), and a precursor containing at least silicon (Si), carbon (C) and nitrogen (N). That is, here, the aminosilane-based precursor may refer to an organic-based precursor or an organic aminosilane-based precursor. The aminosilane-based precursor gas may be a silicon-containing gas (silicon source), a nitrogen containing gas (nitrogen source), or a carbon-containing gas (carbon source). In addition, the term “aminosilane-based precursor” used in the description may refer to “an aminosilane-based precursor in a liquid state,” “an aminosilane-based precursor gas in a gaseous state,” or both of them. For example, a trisdimethylaminosilane (Si[N(CH₃)₂]₃H, abbreviation: 3DMAS) gas may be used as the aminosilane-based precursor gas. In addition, when a liquid precursor in the liquid state under normal temperature and pressure, such as the 3DMAS, is used, the liquid precursor is evaporated by an evaporation system such as an evaporator, a bubbler, or the like, and is supplied as a precursor gas (3DMAS gas).

A reaction gas including a borazine compound, for example, a reaction gas including an alkylborazine compound which is an organic borazine compound, i.e., an organic borazine-based gas (borazine-based gas) is supplied into the process chamber 201 via the MFC 241c, the valve 243c and the second nozzle 249c from the third gas supply pipe 232c.

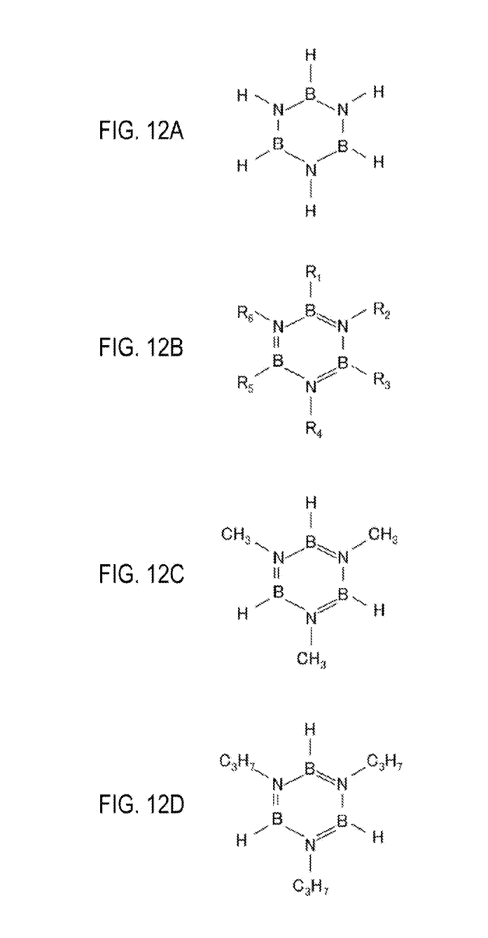

Here, borazine is a heterocyclic compound containing boron (B), nitrogen (N), and hydrogen (H). Borazine may be represented by a composition formula of B₃H₆N₃, and may be represented by a chemical structural formula shown in FIG. 12A. A borazine compound has a borazine ring skeleton (also referred to as a “borazine skeleton”) constituting a borazine ring including three B atoms and three N atoms. An organic borazine compound is a borazine compound containing carbon (C) and may also be referred to as a borazine compound containing a C-containing ligand. An alkylborazine compound is a borazine compound containing an alkyl group and may be referred to as a borazine compound containing an alkyl group as a ligand. The alkylborazine compound is a compound in which at least any one of six hydrogen (H) atoms contained in the borazine compound is substituted with hydrocarbon containing one or more C atoms, and may be represented by a chemical structural formula shown in FIG. 12B. In this case, each of R₁ to R₆ in the chemical structural formula shown in FIG. 12B is a H atom or an alkyl group containing one to four C atoms. R₁ to R₆ may be the same alkyl group or may be different alkyl groups from each other. However, not all of R₁ to R₆ should be H. The alkylborazine compound may indicate a substance having a borazine ring skeleton constituting a borazine ring and containing B, N, H, and C. Also, the alkylborazine compound may indicate a substance having a borazine ring skeleton and containing an alkyl ligand. In addition, each of R₁ to R₆ may an H atom, or an alkenyl group or an alkynyl group containing one to four C atoms. R₁ to R₆ may be the same alkenyl group or alkynyl group, or may be different alkenyl groups or alkynyl groups from each other. However, not all of R₁ to R₆ should be H. The reaction gas including the organic borazine compound may be a boron-containing gas (boron precursor), a nitrogen-containing gas (nitrogen source), and a carbon-containing gas (carbon source).

For example, an n,n′,n″-trimethylborazine (abbreviation: TMB) gas may be used as the reaction gas including the organic borazine compound. The TMB may be represented by a chemical structural formula shown in FIG. 12C in which R₁, R₃, and R₅ of the chemical structural formula in FIG. 12B are H atoms while R₂, R₄, and R₆ of the chemical structural formula in FIG. 12B are methyl groups (—CH₃). The TMB may also be referred to as a borazine compound having a borazine ring skeleton and containing a methyl group as a ligand. In the case of using an organic borazine compound such as TMB which is in a liquid state under normal temperature and pressure, the organic borazine compound in a liquid state may be vaporized by a vaporization system such as a vaporizer or a bubbler to be supplied as the reaction gas including the organic borazine compound (e.g., TMB gas). Further, the reaction gas including the organic borazine compound may be simply referred to as an organic borazine compound gas.

A nitriding gas (i.e., nitrogen-containing gas) is supplied into the process chamber 201 via the MFC 241d, the valve 243d, the fourth nozzle 249d, and the buffer chamber 237 from the fourth gas supply pipe 232d. As the nitriding gas, for example, an ammonia (NH₃) gas may be used.

As a gas containing carbon (C) (i.e., carbon-containing gas), for example, a hydrocarbon-based gas, which is a carbon source, is supplied into the process chamber 201 via the MFC 241i, the valve 243i, the third gas supply pipe 232c, and the third nozzle 249c from the fifth gas supply pipe 232i. As the carbon-containing gas, for example, a propylene (C₃H₆) gas may be used.

As an inert gas, for example, a nitrogen (N₂) gas is supplied from the inert gas supply pipes 232e to 232h into the process chamber 201 via the MFCs 241e to 241h, the valves 243e to 243h, the gas supply pipes 232a to 232d, and the nozzles 249a to 249d and the buffer chamber 237, respectively.

When the above-described gases are respectively flowed through each of the gas supply pipes, a first precursor gas supply system that supplies a first precursor gas containing a predetermined element and a halogen group, i.e., a chlorosilane-based precursor gas supply system, is configured by the first gas supply system. Further, a second precursor gas supply system that supplies a second precursor gas containing a predetermined element and an amino group, i.e., an aminosilane-based precursor gas supply system, is configured by the second gas supply system. Furthermore, the chlorosilane-based precursor gas supply system and the aminosilane-based precursor gas supply system are also simply referred to as a chlorosilane-based precursor supply system and an aminosilane-based precursor supply system, respectively. In addition, a reaction gas supply system that supplies a reaction gas including an organic borazine compound, i.e., an organic borazine-based gas (borazine-based gas) supply system is configured by the third gas supply system. Further, the reaction gas supply system is also referred to as an organic borazine compound gas supply system. Furthermore, a nitriding gas (nitrogen containing gas) supply system is configured by the fourth gas supply system. In addition, a hydrocarbon-based gas supply system as a carbon-containing gas supply system is configured by the fifth gas supply system.

In the buffer chamber 237, as illustrated in FIG. 2, a first rod-shaped electrode 269 that is a first electrode having an elongated structure and a second rod-shaped electrode 270 that is a second electrode having an elongated structure are disposed to span from a lower portion to an upper portion of the reaction tube 203 in the stacking direction of the wafers 200. Each of the first rod-shaped electrode 269 and the second rod-shaped electrode 270 is disposed in parallel to the fourth nozzle 249d. Each of the first rod-shaped electrode 269 and the second rod-shaped electrode 270 is covered with and protected by an electrode protection tube 275, which is a protection tube for protecting each electrode from an upper portion to a lower portion thereof. Any one of the first rod-shaped electrode 269 and the second rod-shaped electrode 270 is connected to a high-frequency power source 273 through a matcher 272, and the other one is connected to a ground corresponding to a reference electric potential. By applying high-frequency power from the high-frequency power source 273 between the first rod-shaped electrode 269 and the second rod-shaped electrode 270 through the matcher 272, plasma is generated in a plasma generation region 224 between the first rod-shaped electrode 269 and the second rod-shaped electrode 270. A plasma source as a plasma generator (plasma generating part) is mainly configured by the first rod-shaped electrode 269, the second rod-shaped electrode 270 and the electrode protection tubes 275. The matcher 272 and the high-frequency power source 273 may also be included in the plasma source. Also, as described later, the plasma source functions as an activating mechanism (exciting unit) that activates (excites) gas into a plasma state.

The electrode protection tube 275 has a structure in which each of the first rod-shaped electrode 269 and the second rod-shaped electrode 270 can be inserted into the buffer chamber 237 in a state where each of the first rod-shaped electrode 269 and the second rod-shaped electrode 270 is isolated from an internal atmosphere of the buffer chamber 237. Here, when an internal oxygen concentration of the electrode protection tube 275 is equal to an oxygen concentration in an ambient air (atmosphere), each of the first rod-shaped electrode 269 and the second rod-shaped electrode 270 inserted into the electrode protection tubes 275 is oxidized by the heat generated by the heater 207. Therefore, by charging the inside of the electrode protection tube 275 with an inert gas such as a nitrogen gas, or by purging the inside of the electrode protection tube 275 with an inert gas such as a nitrogen gas using an inert gas purging mechanism, the internal oxygen concentration of the electrode protection tube 275 decreases, thereby preventing oxidation of the first rod-shaped electrode 269 or the second rod-shaped electrode 270.

The exhaust pipe 231 for exhausting an internal atmosphere of the process chamber 201 is installed at the reaction tube 203. A vacuum exhaust device, for example, a vacuum pump 246, is connected to the exhaust pipe 231 through a pressure sensor 245, which is a pressure detector (pressure detecting part) for detecting an internal pressure of the process chamber 201, and an auto pressure controller (APC) valve 244, which is a pressure adjuster (pressure adjusting part). The APC valve 244 is configured to perform/stop vacuum exhaust in the process chamber 201 by opening/closing the valve with the vacuum pump 246 actuated, and further to adjust the internal pressure of the process chamber 201 by adjusting a degree of the valve opening with the vacuum pump 246 actuated. An exhaust system is mainly configured by the exhaust pipe 231, the APC valve 244, and the pressure sensor 245. Also, the vacuum pump 246 may be included in the exhaust system. The exhaust system is configured to adjust the degree of the valve opening of the APC valve 244 based on pressure information detected by the pressure sensor 245 while actuating the vacuum pump 246 such that the internal pressure of the process chamber 201 is vacuum exhausted to a predetermined pressure (a vacuum level).

A seal cap 219, which functions as a furnace port cover configured to hermetically seal a lower end opening of the reaction tube 203, is installed under the reaction tube 203. The seal cap 219 is configured to contact the lower end of the reaction tube 203 from the below in the vertical direction. The seal cap 219, for example, may be formed of metal such as stainless and have a disc shape. An O-ring 220, which is a seal member in contact with the lower end portion of the reaction tube 203, is installed at an upper surface of the seal cap 219. A rotary mechanism 267 configured to rotate the boat 217, which is a substrate holder to be described later, is installed below the seal cap 219. A rotary shaft 255 of the rotary mechanism 267 passes through the seal cap 219 to be connected to the boat 217. The rotary mechanism 267 is configured to rotate the wafers 200 by rotating the boat 217. The seal cap 219 is configured to be vertically elevated or lowered by a boat elevator 115, which is an elevation mechanism vertically disposed in the outside of the reaction tube 203. The boat elevator 215 configured to enable the boat 217 to be loaded into or unloaded from the process chamber 201 by elevating or lowering the seal cap 219. That is, the boat elevator 115 is configured as a transfer device (transfer mechanism) that transfers the boat 217, i.e., the wafers 200, into and out of the process chamber 201.

The boat 217, which is used as a substrate support, is made of a heat resistant material such as quartz or silicon carbide and is configured to support a plurality of the wafers 200 horizontally stacked in multiple stages with the centers of the wafers 200 concentrically aligned. In addition, a heat insulating member 218 made of a heat resistant material such as quartz or silicon carbide is installed at a lower portion of the boat 217 and configured such that heat from the heater 207 cannot be transferred to the seal cap 219. In addition, the heat insulating member 218 may be configured by a plurality of heat insulating plates made of a heat resistant material such as quartz or silicon carbide, and a heat insulating plate holder configured to support the heat insulating plates horizontally in multiple stages.

A temperature sensor 263, which is a temperature detector, is installed in the reaction tube 203. Based on temperature information detected by the temperature sensor 263, an electric conduction state to the heater 207 is adjusted such that the interior of the process chamber 201 has a desired temperature distribution. The temperature sensor 263 is configured in an L-shape similar to the nozzles 249a to 249d and installed along the inner wall of the reaction tube 203.

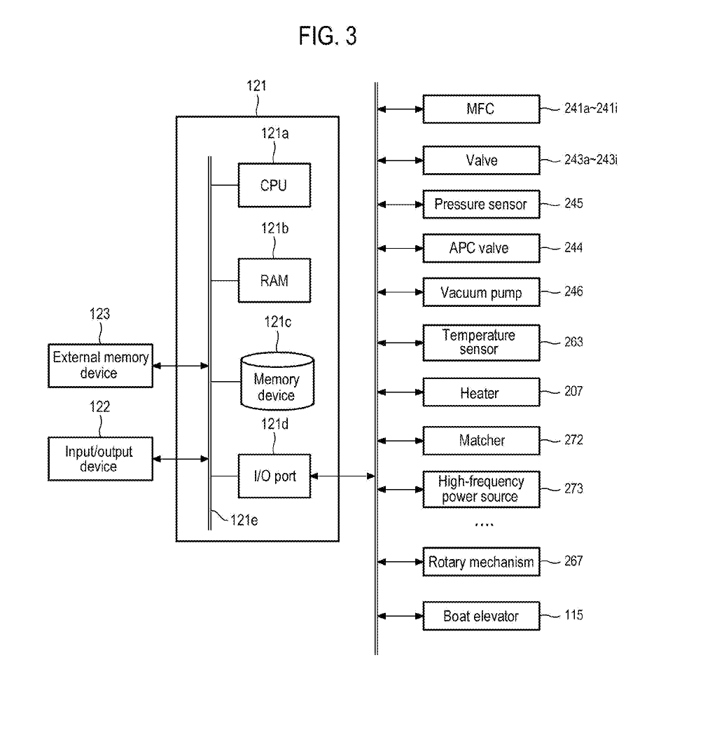

As illustrated in FIG. 3, a controller 121, which is a control unit (control part), is configured as a computer including a central processing unit (CPU) 121a, a random access memory (RAM) 121b, a memory device 121c, and an I/O port 121d. The RAM 121b, the memory device 121c and the I/O port 121d are configured to exchange data with the CPU 121a via an internal bus 121e. An input/output device 122, for example, including a touch panel or the like, is connected to the controller 121.

The memory device 121c is configured by, for example, a flash memory, a hard disc drive (HDD, or the like. A control program for controlling operation of the substrate processing apparatus or a process recipe, in which a sequence or condition for processing a substrate described later is written, is readably stored in the memory device 121c. Also, the process recipe functions as a program for the controller 121 to execute each sequence in the substrate processing process, which will be described later, to obtain a predetermined result. Hereinafter, the process recipe or control program may be generally referred to as “a program.” Also, when the term “program” is used herein, it may include the case in which only the process recipe is included, the case in which only the control program is included, or the case in which both of the process recipe and the control program are included. In addition, the RAM 121b is configured as a memory area (work area) in which a program or data read by the CPU 121a is temporarily stored.

The I/O port 121d is connected to the above-described MFCs 241a to 241i, the valves 243a to 243i, the pressure sensor 245, the APC valve 244, the vacuum pump 246, the heater 207, the temperature sensor 263, the high-frequency power source 273, the matcher 272, the rotary mechanism 267, the boat elevator 115 and the like.

The CPU 121a is configured to read and execute the control program from the memory device 121c. According to an input of an operation command from the input/output device 122, the CPU 121a reads the process recipe from the memory device 121c. In addition, the CPU 121a is configured to control a flow rate controlling operation of various types of gases by the MFCs 241a to 241i, an opening/closing operation of the valves 243a to 243i, an opening/closing operation of the APC valve 244 and a pressure adjusting operation by the APC valve 244 based on the pressure sensor 245, a start/stop operation of the vacuum pump 246, a temperature adjusting operation of the heater 207 based on the temperature sensor 263, a power supply operation of the high-frequency power source 273, an impedance adjusting operation of the matcher 272, a rotation and rotation speed adjusting operation of the boat 217 by the rotary mechanism 267, an elevation operation of the boat 217 by the boat elevator 115, and the like according to contents of the read process recipe.

Moreover, the controller 121 is not limited to being configured as a dedicated computer but may be configured as a general-purpose computer. For example, the controller 121 according to some embodiments may be configured by preparing an external memory device 123 (for example, a magnetic tape, a magnetic disc such as a flexible disc or a hard disc, an optical disc such as a CD or DVD, a magneto-optical disc such as an MO, a semiconductor memory such as a USB memory or a memory card), in which the program is stored, and installing the program on the general-purpose computer using the external memory device 123. Also, a means for supplying the program to the computer is not limited to the case in which the program is supplied through the external memory device 123. For example, the program may be supplied using a communication means such as the Internet or a dedicated line, rather than through the external memory device 123. Also, the memory device 121c or the external memory device 123 is configured as a non-transitory computer-readable recording medium. Hereinafter, these means for supplying the program will be simply referred to as “a recording medium.” In addition, when the term “recording medium” is used herein, it may include a case in which only the memory device 121c is included, a case in which only the external memory device 123 is included, or a case in which both the memory device 121c and the external memory device 123 are included.

### (2) Substrate Processing Process

Next, an example of a sequence of forming a thin film on a substrate, which is one of the processes of manufacturing a semiconductor device by using the processing furnace 202 of the above-described substrate processing apparatus, will be described. In addition, in the following description, operations of the respective parts constituting the substrate processing apparatus are controlled by the controller 121.

In a film forming sequence according to a first embodiment, a thin film containing a predetermined element, boron (B), carbon (C), and nitrogen (N) and having a borazine ring skeleton is formed on a substrate by performing a cycle a predetermined number of times. The cycle includes: supplying a first precursor gas containing the predetermined element and a halogen group to the substrate; supplying a second precursor gas containing the predetermined element and an amino group to the substrate; supplying a reaction gas including an organic borazine compound to the substrate; and supplying a carbon-containing gas to the substrate. The cycle is performed under a condition in which the borazine ring skeleton in the organic borazine compound is maintained.

Specifically, a thin film containing a predetermined element, boron (B), carbon (C), and nitrogen (N) and having a borazine ring skeleton is formed on a substrate by performing a cycle a first predetermined number of times. The cycle includes: forming a first layer containing the predetermined element, a halogen group, carbon (C), and nitrogen (N) by performing a set a second predetermined number of times, the set including: supplying a first precursor gas containing the predetermined element and the halogen group to the substrate; and supplying a second precursor gas containing the predetermined element and an amino group to the substrate; and forming a second layer containing the predetermined element, boron (B), carbon (C), and nitrogen (N) and having the borazine ring skeleton by supplying a reaction gas, which contains an organic borazine compound, to the substrate and thereby reacting the first layer with the organic borazine compound to modify the first layer under a condition in which the borazine ring skeleton in the organic borazine compound is maintained.

Herein, the process of supplying the carbon-containing gas to the substrate is performed in at least one of the process of supplying the first precursor gas, the process of supplying the second precursor gas, and the process of supplying the reaction gas. For example, the process of supplying the carbon-containing gas to the substrate may be performed during the process of supplying the reaction gas.

In addition, in the process of forming the first layer, for example, the process of supplying the first precursor gas and the process of supplying the second precursor gas may be performed alternately a predetermined number of times. That is, the process of supplying the first precursor gas and the process of supplying the second precursor gas are set as one set and this set is performed one or more times. The case of performing this set once corresponds to a first sequence described later and the case of performing this set multiple times corresponds to a second sequence described later. Moreover, as described later, in the process of forming the first layer, for example, the process of supplying the first precursor gas and the process of supplying the second precursor may be performed simultaneously a predetermined number of times (one or more times).

In addition, the phrase “performing a cycle a predetermined number of times, the cycle including forming a first layer and forming a second layer” means that, if the process of forming the first layer and the process of forming the second layer are set as one cycle, the cycle is performed one or more times. That is, the phrase means that the cycle is performed at least one time. In other words, the phrase may mean that the cycle of alternately performing the process of forming the first layer and the process of forming the second layer is performed one time or repeated a plurality number of times. However, it may be preferred that the cycle is repeated a plurality number of times.

In addition, the phrase “the process of supplying the carbon-containing gas to the substrate is performed in at least one of the process of supplying the first precursor gas, the process of supplying the second precursor gas, and the process of supplying the reaction gas” may mean that, during at least one of the process of supplying the first precursor gas, the process of supplying the second precursor gas, and the process of supplying the reaction gas, the process of supplying the carbon-containing gas is performed in at least a portion of a period during which a gas used in each process among the first precursor gas, the second precursor gas and the reaction gas is supplied.

Further, in the process of supplying the first precursor gas, the process of supplying the second precursor gas and the process of supplying the reaction gas, the gas supply in each process may be initiated after a predetermined time has passed after the process is initiated, or the process may be terminated after a predetermined time has passed after the gas supply in each process is terminated. That is, the process of supplying the first precursor gas, the process of supplying the second precursor gas and the process of supplying the reaction gas may include a supply stop period (a period before starting the gas supply and/or a period after stopping the gas supply) of the gas for each process, as well as a supply period of the gas for each process. In the above case, the phrase “the process of supplying the carbon-containing gas to the substrate is performed in at least one of the process of supplying the first precursor gas, the process of supplying the second precursor gas, and the process of supplying the reaction gas” may mean that the supply of the carbon-containing gas is performed in the supply stop period (a period before starting the supply of a gas and/or a period after stopping the supply of a gas), not in the supply period for the first precursor gas, the second precursor gas and/or the reaction gas. In addition, it may mean that the supply of the carbon-containing gas is performed in both of the supply period and the supply stop period for the first precursor gas, the second precursor gas and/or the reaction gas.

### (First Sequence)

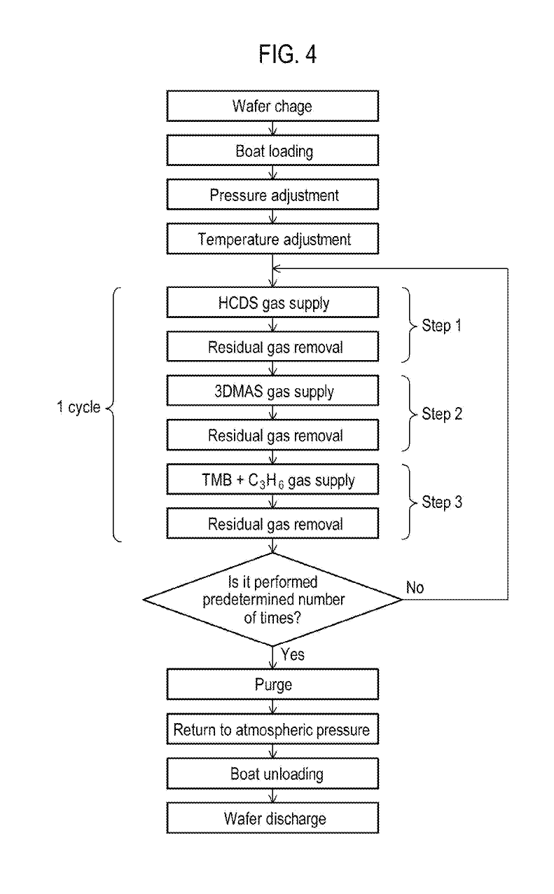

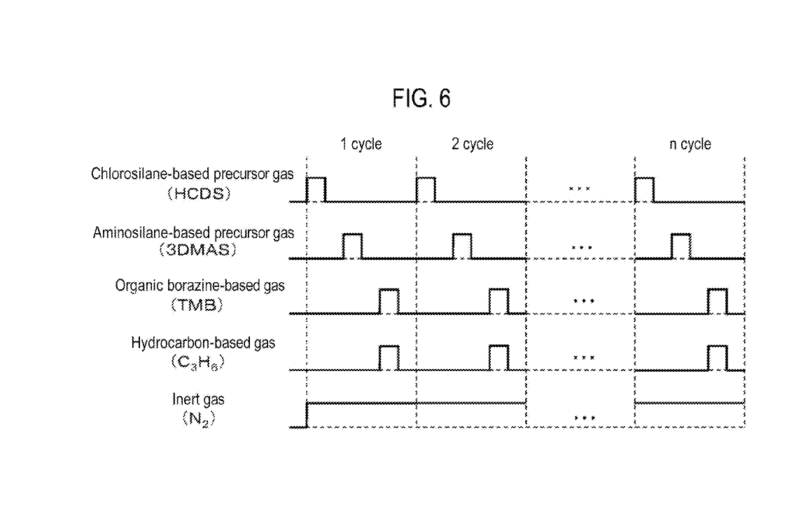

Hereinafter, a first sequence of the first embodiment will be described. FIG. 4 is a view showing a film-forming flow in the first sequence of the first embodiment of the present disclosure. FIG. 6 is a view showing gas supply timing in the first sequence of the first embodiment of the present disclosure.

In the first sequence of the first embodiment, a thin film containing silicon (Si), boron (B), carbon (C), and nitrogen (N) and having a borazine ring skeleton (hereinafter, which may also be referred to as a SiBCN film having a borazine ring skeleton) is formed on the wafer 200, by performing a cycle a first predetermined number of times. The cycle includes: forming a SiCN layer containing chlorine (Cl) as a first layer containing silicon (Si), chlorine (Cl), carbon (C) and nitrogen (N), by performing a set a second predetermined number of times (once), the set including: supplying an HCDS gas as a first precursor gas containing silicon (Si) and a chloro group to the wafer 200; and supplying a 3DMAS gas as a second precursor gas containing silicon (Si) and an amino group to the wafer 200; and forming a SiBCN layer having the borazine ring skeleton, as a second layer containing silicon (Si), boron (B), carbon (C), and nitrogen (N) and having the borazine ring skeleton, by supplying a TMB gas as a reaction gas, which contains an organic borazine compound, to the wafer 200 and thereby reacting the first layer with the organic borazine compound to modify the first layer under a condition in which the borazine ring skeleton in the organic borazine compound is maintained. In addition, hereinafter, for convenience, the SiBCN film (or layer) having the borazine ring skeleton may be simply referred to as a SiBCN film (or layer).

In addition, herein, the C₃H₆ gas as the carbon-containing gas is supplied onto the wafer 200 while supplying the TMB gas. In addition, while supplying the TMB gas, the C₃H₆ gas is supplied during the supply period of the TMB gas. That is, the TMB gas and the C₃H₆ gas are simultaneously supplied to the wafer 200 during the supply period of the TMB gas.

Moreover, when the term “wafer” is used herein, it may refer to “the wafer itself” or “a laminated body (a collected body) of a wafer and layers or films formed on a surface of the wafer (i.e., a wafer including layers or films formed on the surface of the wafer).” In addition, the phrase “a surface of a wafer” as used herein may refer to “a surface (an exposed surface) of a wafer itself” or “a surface of a layer or a film formed on an outermost surface of a wafer as a laminated body.”

Accordingly, the phrase “a predetermined gas is supplied to a wafer” may mean that “a predetermined gas is directly supplied to a surface (an exposed surface) of a wafer itself” or that “a predetermined gas is supplied to a layer or a film formed on a wafer, i.e., on an uppermost surface of a wafer as a laminated body.” Also, the phrase “a predetermined layer (or film) is formed on a wafer” may mean that “a predetermined layer (or film) is directly formed on a surface (an exposed surface) of a wafer itself” or that “a predetermined layer (or film) is formed on a layer or a film formed on a wafer, i.e., on an uppermost surface of a wafer as a laminated body.”

Moreover, the term “substrate” as used herein may be synonymous with the term “wafer,” and in this case, the terms “wafer” and “substrate” may be used interchangeably in the above description.

### (Wafer Charging and Boat Loading)

When the plurality of wafers 200 are charged on the boat 217 (wafer charging), as illustrated in FIG. 1, the boat 217 supporting the plurality of wafers 200 is raised by the boat elevator 115 to be loaded into the process chamber 201 (boat loading). In this state, the seal cap 219 seals the lower end of the reaction tube 203 via the O-ring 220.

### (Pressure Adjustment and Temperature Adjustment)

The internal pressure of the process chamber 201, that is, the pressure of a space where the wafers 200 exist is vacuum-exhausted by the vacuum pump 246 to a desired pressure (vacuum level). Here, the internal pressure of the process chamber 201 is measured by the pressure sensor 245, and the APC valve 244 is feedback-controlled based on the measured pressure information (pressure adjustment). Also, the vacuum pump 246 remains activated at least until processing of the wafers 200 is completed. Further, the wafers 200 in the process chamber 201 are heated by the heater 207 to a desired temperature. Here, an electrical conduction state to the heater 207 is feedback-controlled based on the temperature information detected by the temperature sensor 263 until the interior of the process chamber 201 reaches a desired temperature distribution (temperature adjustment). In addition, heating of the interior of the process chamber 201 by the heater 207 is continuously performed at least until processing of the wafers 200 is completed. Next, the boat 217 and wafers 200 begin to be rotated by the rotary mechanism 267. Furthermore, the rotation of the boat 217 and wafers 200 by the rotary mechanism 267 is continuously performed at least until processing of the wafers 200 is completed.

### (SiBCN Film Forming Process)

Next, the following three steps, i.e., Steps 1 to 3 are sequentially performed.

### [Step 1]

### (HCDS Gas Supply)

The valve 243a of the first gas supply pipe 232a is opened to cause the HCDS gas to flow through the first gas supply pipe 232a. The HCDS gas flowing through the first gas supply pipe 232a is flow rate-adjusted by the MFC 241a. The flow rate-adjusted HCDS gas is supplied into the process chamber 201 through the gas supply holes 250a of the first nozzle 249a to be exhausted through the exhaust pipe 231. As such, the HCDS gas is supplied to the wafer 200 (HCDS gas supply). At the same time, the valve 243e is opened to cause an inert gas, such as a N₂ gas, to flow through the first inert gas supply pipe 232e. The N₂ gas flowing through the first inert gas supply pipe 232e is flow rate-adjusted by the MFC 241e. The flow rate-adjusted N₂ gas is supplied into the process chamber 201 to be exhausted through the exhaust pipe 231 with the HCDS gas.

At this time, in order to prevent infiltration of the HCDS gas into the second nozzle 249b, the third nozzle 249c, the fourth nozzle 249d, and the buffer chamber 237, the valves 243f, 243g and 243h are opened to cause the N₂ gas to flow through the second inert gas supply pipe 232f, and the third inert gas supply pipe 232g and the fourth inert gas supply pipe 232h. The N₂ gas is supplied into the process chamber 201 to be exhausted through the exhaust pipe 231 via the second gas supply pipe 232b, the third gas supply pipe 232c, the fourth gas supply pipe 232d, the second nozzle 249b, the third nozzle 249c, the fourth nozzle 249d and the buffer chamber 237.

In this case, the APC valve 244 is appropriately adjusted such that the pressure in the process chamber 201 falls within a range of, for example, 1 to 13,300 Pa, more specifically 20 to 1,330 Pa. A supply flow rate of the HCDS gas controlled by the MFC 241a is set to fall within a range of, for example, 1 to 1,000 sccm. A supply flow rate of the N₂ gas controlled by the MFCs 241e to 241h is set to fall within a range of, for example, 100 to 10,000 sccm. A time period during which the HCDS gas is supplied to the wafer 200, i.e., a gas supply time (an irradiation time), is set to fall within a range of, for example, 1 to 120 seconds, more specifically 1 to 60 seconds. At this time, a temperature of the heater 207 is set such that the temperature of the wafer 200 falls within a range of, for example, 250 to 700 degrees C., more specifically 300 to 650 degrees C., or further more specifically 350 to 600 degrees C. In addition, when the temperature of the wafer 200 is less than 250 degrees C., a practical film-forming speed may not be accomplished because the HCDS cannot be easily chemisorbed on the wafer 200. This problem can be solved by increasing the temperature of the wafer 200 to 250 degrees C. or more. Further, by setting the temperature of the wafer 200 to 300 degrees C. or more, or more specifically 350 degrees C. or more, the HCDS can be more sufficiently adsorbed on the wafer 200, and a more sufficient film-forming speed can be obtained. In addition, when the temperature of the wafer 200 exceeds 700 degrees C., a CVD reaction is strengthened (a gas phase reaction becomes dominant), and thus film thickness uniformity is likely to be degraded to make it difficult to control the film thickness uniformity. When the temperature of the wafer 200 is set to 700 degrees C. or less, degradation of the film thickness uniformity can be suppressed and it becomes possible to control the film thickness uniformity. In particular, when the temperature of the wafer 200 is set to 650 degrees C. or less, or more specifically 600 degrees C. or less, the surface reaction becomes dominant, and the film thickness uniformity can be easily accomplished to enable easy control thereof. Accordingly, the temperature of the wafer 200 may be set to fall within a range of 250 to 700 degrees C., more specifically 300 to 650 degrees C., or further more specifically 350 to 600 degrees C.

A silicon-containing layer containing chlorine (Cl) and having a thickness of, for example, less than one atomic layer to several atomic layers is formed on the wafer 200 (a base film of the surface) by supplying the HCDS gas to the wafer 200 under the above-described conditions. The silicon-containing layer containing chlorine (Cl) may include an adsorption layer of the HCDS gas, a silicon layer (a Si layer) containing Cl, or both of them.

Here, the phrase “silicon layer containing Cl” is a generic name which encompasses a continuous or discontinuous layer that is formed of Si and contains Cl, and a Si thin film containing Cl that is formed by laminating such layers. The continuous layer that is formed of Si and contains Cl may be referred to as a silicon thin film containing Cl. In addition, Si constituting the silicon layer containing Cl contains Si whose bond to Cl is completely broken, in addition to Si whose bond to Cl is not completely broken.

The adsorption layer of the HCDS gas includes a continuous chemical adsorption layer in which gas molecules of the HCDS gas are continuous, and a discontinuous chemical adsorption layer in which gas molecules of the HCDS gas are discontinuous. In other words, the adsorption layer of the HCDS gas may include a chemical adsorption layer formed of HCDS molecules and having a thickness of one molecular layer or less than one molecular layer. Further, HCDS (Si₂Cl₆) molecules that constitute the adsorption layer of the HCDS gas include one or more molecules in which a bond between Si and Cl is partially broken.

In addition, a layer having a thickness of less than one atomic layer means an atomic layer that is discontinuously formed, and a layer having a thickness of one atomic layer means an atomic layer that is continuously formed. Further, a layer having a thickness of less than one molecular layer means a molecular layer that is discontinuously formed, and a layer having a thickness of one molecular layer means a molecular layer that is continuously formed.

Under a condition in which the HCDS gas is autolyzed (or pyrolyzed), i.e., under a condition in which a pyrolysis reaction of the HCDS gas occurs, Si is deposited on the wafer 200 to form the silicon layer containing Cl. Under a condition in which the HCDS gas is not autolyzed (or pyrolyzed), i.e., under a condition in which a pyrolysis reaction of the HCDS gas does not occur, the HCDS gas is adsorbed onto the wafer 200 to form the adsorption layer of the HCDS gas. In addition, a film-forming rate may be increased when the silicon layer containing Cl is formed on the wafer 200, rather than when the adsorption layer of the HCDS gas is formed on the wafer 200.

When the thickness of the silicon-containing layer containing Cl formed on the wafer 200 exceeds several atomic layers, an effect of a modification reaction in Steps 2 and 3 described later is not applied to the entire silicon-containing layer containing Cl. In addition, a minimum value of the thickness of the silicon-containing layer containing Cl to be formed on the wafer 200 is less than one atomic layer. Accordingly, the thickness of the silicon-containing layer containing Cl may be set to fall within a range of less than one atomic layer to several atomic layers. Further, when the thickness of the silicon-containing layer containing Cl is set to be one atomic layer or less, i.e., one atomic layer or less than one atomic layer, the effect of the modification reaction in Steps 2 and 3 described later can be relatively increased, and the time required for the modification reaction in Steps 2 and 3 can be reduced. The time required to form the silicon-containing layer containing Cl in Step 1 can also be reduced. Eventually, a processing time per cycle can be reduced, and a total processing time can also be reduced. That is, the film-forming rate can also be increased. In addition, when the thickness of the silicon-containing layer containing Cl is set to one atomic layer or less, the controllability of the film thickness uniformity can also be improved.

### (Residual Gas Removal)

After the silicon-containing layer containing Cl is formed, the valve 243a of the first gas supply pipe 232a is closed to stop the supply of the HCDS gas. At this time, the interior of the process chamber 201 is vacuum-exhausted by the vacuum pump 246 in a state in which the APC valve 244 of the exhaust pipe 231 is in an open state, and the HCDS gas in the process chamber 201 which has not reacted or remains after contributing to the formation of the silicon-containing layer containing Cl is removed from the process chamber 201 (residual gas removal). In this operation, the supply of the N2 gas as an inert gas into the process chamber 201 is maintained while the valves 243e to 243h are in an open state. The N₂ gas serves as a purge gas, and thereby the HCDS gas, which has not reacted or remains after contributing to the formation of the silicon-containing layer containing Cl, can be more effectively removed from the process chamber 201.

In addition, the gas remaining in the process chamber 201 may not be completely removed, and the interior of the process chamber 201 may not be completely purged. When the gas remaining in the process chamber 201 is minute, there is no adverse effect to be generated in Step 2 performed thereafter. Here, an amount of the N₂ gas supplied into the process chamber 201 need not be a large amount. For example, approximately the same amount of the N₂ gas as the volume of the reaction tube 203 (or the process chamber 201) may be supplied to perform the purge such that there is no adverse effect to be generated in Step 2. As described above, as the interior of the process chamber 201 is not completely purged, the purge time can be reduced and thus the throughput can be improved. In addition, the consumption of the N₂ gas can also be suppressed to a minimal necessity.

As the chlorosilane-based precursor gas, an inorganic precursor gas such as a tetrachlorosilane gas, i.e., a silicon tetrachloride (SiCl₄, abbreviation: STC) gas, a trichlorosilane (SiHCl₃, abbreviation: TCS) gas, a dichlorosilane (SiH₂Cl₂, abbreviation: DCS) gas, a monochlorosilane (SiH₃Cl, abbreviation: MCS) gas, or the like, may be used in addition to the hexachlorodisilane (Si₂Cl₆, abbreviation: HCDS) gas. As the inert gas, a rare gas such as an Ar gas, a He gas, a Ne gas, a Xe gas, or the like, may be used.

### [Step 2]

### (3DMAS Gas Supply)

After Step 1 is completed and the residual gas in the process chamber 201 is removed, the valve 243b of the second gas supply pipe 232b is opened to cause the 3DMAS gas to flow through the second gas supply pipe 232b. The 3DMAS gas flowing through the second gas supply pipe 232b is flow rate-adjusted by the MFC 241b. The flow rate-adjusted 3DMAS gas is supplied into the process chamber 201 from the gas supply holes 250b of the second nozzle 249b to be exhausted through the exhaust pipe 231. Here, the 3DMAS gas is supplied to the wafer 200 (3DMAS gas supply). At the same time, the valve 243f is opened to cause the N₂ gas serving as an inert gas to flow into the second inert gas supply pipe 232f. The N₂ gas flowing through the second inert gas supply pipe 232f is flow rate-adjusted by the MFC 241f. The flow rate-adjusted N₂ gas is supplied into the process chamber 201 to be exhausted through the exhaust pipe 231 with the 3DMAS gas.

In addition, in order to prevent infiltration of the 3DMAS gas into the first nozzle 249a, the third nozzle 249c, the fourth nozzle 249d, and the buffer chamber 237, the valves 243e, 243g, and 243h are opened to cause the N₂ gas to flow through the first inert gas supply pipe 232e, the third inert gas supply pipe 232g, and the fourth inert gas supply pipe 232h. The N₂ gas is supplied into the process chamber 201 to be exhausted through the exhaust pipe 231 via the first gas supply pipe 232a, the third gas supply pipe 232c, the fourth gas supply pipe 232d, the first nozzle 249a, the third nozzle 249c, the fourth nozzle 249d, and the buffer chamber 237.

In this case, the APC valve 244 is appropriately adjusted such that the pressure in the process chamber 201 is set to fall within a range of, for example, 1 to 13,300 Pa, more specifically 20 to 1330 Pa. A supply flow rate of the 3DMAS gas controlled by the MFC 241b is set to fall within a range of, for example, 1 to 1000 sccm. A supply flow rate of the N₂ gas controlled by the MFCs 241e to 241h is set to fall within a range of, for example, 100 to 10,000 sccm. A time period during which the 3DMAS gas is supplied to the wafer 200, i.e., a gas supply time (an irradiation time) is set to fall within a range of, for example, 1 to 120 seconds, more specifically, 1 to 60 seconds. Here, similarly to Step 1, the temperature of the heater 207 is set such that the temperature of the wafer 200 falls within a range of, for example, 250 to 700 degrees C., more specifically 300 to 650 degrees C., or further more specifically 350 to 600 degrees C.

By supplying the 3DMAS gas to the wafer 200 under the above-described conditions, the 3DMAS gas reacts with the silicon-containing layer containing Cl, which is formed on the wafer 200 in Step 1. Thereby, the silicon-containing layer containing Cl is changed into the first layer containing silicon (Si), chlorine (Cl), carbon (C), and nitrogen (N), i.e., the SiCN layer containing Cl (modification). The first layer becomes a layer with a thickness of, for example, less than one atomic layer to several atomic layers. In addition, the first layer becomes a layer having a relatively high ratios of a Si component and a C component, i.e., a Si-rich and C-rich layer.

### (Residual Gas Removal)

After the first layer is formed, the valve 243b of the second gas supply pipe 232b is closed to stop the supply of the 3DMAS gas. At this time, the interior of the process chamber 201 is vacuum-exhausted by the vacuum pump 246 in a state in which the APC valve 244 of the exhaust pipe 231 is in an open state, and the 3DMAS gas, which has not reacted or remains after contributing to the formation of the first layer, or reaction byproduct is removed from the process chamber 201 (residual gas removal). In this operation, the supply of the N₂ gas as an inert gas into the process chamber 201 is maintained while the valves 243e to 243h are in an open state. The N₂ gas serves as a purge gas, and thereby the 3DMAS gas, which has not reacted or remains after contributing to the formation of the first layer, or reaction byproduct can be more effectively removed from the process chamber 201.

In this case, the gas remaining in the process chamber 201 may not be completely removed, and the interior of the process chamber 201 may not be completely purged. When the gas remaining in the process chamber 201 is minute, no adverse effect is generated in Step 3 performed thereafter. Here, an amount of the N₂ gas supplied into the process chamber 201 need not be a large amount. For example, approximately the same amount of the N₂ gas as the volume of the reaction tube 203 (or the process chamber 201) may be supplied to perform the purge such that there is no adverse effect to be generated in Step 3. As described above, as the interior of the process chamber 201 is not completely purged, the purge time can be reduced and thus the throughput can be improved. In addition, the consumption of the N₂ gas can also be suppressed to a minimal necessity.

As the aminosilane-based precursor gas, an organic precursor gas such as a tetrakis(dimethylamino)silane (Si[N(CH₃)₂]₄, abbreviation: 4DMAS) gas, a bis(diethylamino)silane (Si[N(C₂H₅)₂]₂H₂, abbreviation: 2DEAS) gas, a bis(tert-butylamino)silane (SiH₂[NH(C₄H₉)]₂, abbreviation: BTBAS) gas, or the like, may be used in addition to the 3DMAS gas. As the inert gas, a rare gas such as an Ar gas, a He gas, a Ne gas, a Xe gas, or the like, may be used in addition to the N₂ gas.

### [Step 3]

### (TMB Gas and C₃H₆ Gas Supply)

After Step 2 is completed and the residual gas in the process chamber 201 is removed, the valve 243c of the third gas supply pipe 232c is opened to cause the TMB gas to flow through the third gas supply pipe 232c. The TMB gas flowing through the third gas supply pipe 232c is flow rate-adjusted by the MFC 241c. The flow rate-adjusted TMB gas is supplied into the process chamber 201 from the gas supply holes 250c of the third nozzle 249c to be exhausted through the exhaust pipe 231. At the same time, the valve 243g is opened to cause the N₂ gas as an inert gas to flow through the third inert gas supply pipe 232g. The N₂ gas flowing through the third inert gas supply pipe 232g is flow rate-adjusted by the MFC 241g. The flow rate-adjusted N₂ gas is supplied into the process chamber 201 to be exhausted through the exhaust pipe 231 with the TMB gas.

At the same time, the valve 243i of the fifth gas supply pipe 232i is opened to cause the C₃H₆ gas to flow through the fifth gas supply pipe 232i. The C₃H₆ gas flowing through the fifth gas supply pipe 232i is flow rate-adjusted by the MFC 241i. The flow rate-adjusted C₃H₆ gas flows through the third gas supply pipe 232c and is supplied into the process chamber 201 from the gas supply holes 250c of the third nozzle 249c.

Each of the TMB gas and the C₃H₆ gas supplied into the process chamber 201 is thermally activated (excited) and exhausted through the exhaust pipe 231 with the N₂ gas supplied from the third inert gas supply pipe 232g. In this way, the thermally activated TMB gas and the thermally activated C₃H₆ gas are simultaneously supplied to the wafer 200.

At this time, in order to prevent infiltration of the TMB gas or the C₃H₆ gas into the first nozzle 249a, the second nozzle 249b, the fourth nozzle 249d, and the buffer chamber 237, the valves 243e, 243f, and 243h are opened to cause the N₂ gas to flow through the first inert gas supply pipe 232e, the second inert gas supply pipe 232f, and the fourth inert gas supply pipe 232h. The N₂ gas is supplied into the process chamber 201 via the first gas supply pipe 232a, the second gas supply pipe 232b, the fourth gas supply pipe 232d, the first nozzle 249a, the second nozzle 249b, the fourth nozzle 249d, and the buffer chamber 237 to be exhausted through the exhaust pipe 231.

In this case, the APC valve 244 is appropriately adjusted such that the pressure in the process chamber 201 is set to fall within a range of, for example, 1 to 13300 Pa, more specifically 500 to 5000 Pa. As the pressure in the process chamber 201 is set to such a relatively high pressure, the TMB gas and the C₃H₆ gas can be thermally activated under non-plasma condition. In addition, since the TMB gas and the C₃H₆ gas are thermally activated and supplied, a soft reaction can be generated, and the modification (to be described below) can be softly performed. A supply flow rate of the TMB gas controlled by the MFC 241c is set to fall within a range of, for example, 1 to 1000 sccm. A supply flow rate of the C₃H₆ gas controlled by the MFC 241i is set to fall within a range of, for example, 100 to 10,000 sccm. A supply flow rate of the N₂ gas controlled by the MFCs 241e to 241h is set to fall within a range of, for example, 100 to 10,000 sccm. Here, a partial pressure of the TMB gas in the process chamber 201 is set to fall within a range of 0.01 to 12,667 Pa. In addition, a partial pressure of the C₃H₆ gas in the process chamber 201 is set to fall within a range of 0.01 to 13,168 Pa. A time period during which the thermally activated TMB gas and the thermally activated C₃H₆ gas are supplied to the wafer 200, i.e., a gas supply time (an irradiation time) is set to fall within a range of, for example, 1 to 120 seconds, more specifically 1 to 60 seconds. Here, similarly to Steps 1 and 2, the temperature of the heater 207 is set such that the temperature of the wafer 200 falls within a range of, for example, 250 to 700 degrees C., more specifically 300 to 650 degrees C., or further more specifically 350 to 600 degrees C.

By supplying the TMB gas to the wafer 200 under the above-described conditions, the TMB gas reacts with the SiCN layer containing Cl, which is the first layer formed on the wafer 200 in Step 2. That is, it is possible to cause the Cl (chloro group) contained in the first layer to react with a ligand (methyl group) containing in the TMB. Thereby, the Cl of the first layer, which has reacted with the ligands of the TMB, can be separated (or extracted) from the first layer, and simultaneously, the ligand of the TMB, which has reacted with the Cl of the first layer, may also be separated from the TMB. Further, N in a borazine ring of the TMB, from which the ligand is separated, can be bonded to Si of the first layer. Thus, among B and N constituting the borazine ring of the TMB, N that is enabled to have an uncombined hand (i.e., dangling bond) due to the separation of the metal ligand may be bonded to Si contained in the first layer that has a dangling bond or is enabled to have a dangling bond, thereby forming a Si—N bond. At this time, the borazine ring skeleton constituting the borazine ring of the TMB is maintained without being broken.

In addition, by supplying the C₃H₆ gas while supplying the TMB gas, specifically, by supplying the C₃H₆ gas during a period of supplying the TMB gas, the C component in the C₃H₆ gas is newly introduced in the first layer. Specifically, by supplying the C₃H₆ gas to the wafer 200, the C₃H₆ gas is adsorbed onto the surface of the first layer and thus, the C component in the C₃H₆ gas is newly introduced into the first layer. Here, for example, Si—C bonds may also be generated since C in the C₃H₆ gas is bonded to Si in the first layer.

As the TMB gas and the C₃H₆ gas are supplied under the conditions as described above, the first layer, the TMB gas, and the C₃H₆ gas may appropriately react with one another while the borazine ring skeleton in the TMB is maintained without being broken and thus, it is possible to cause a series of the above-described reactions. In addition, the most important factors (or conditions) for causing the series of the above-described reactions in a state where the borazine ring skeleton of the TMB is maintained are the temperature of the wafer 200 and the internal pressure of the process chamber 201, especially the temperature of the wafer 200. Thus, it is possible to cause appropriate reactions by appropriately controlling those factors.

Through the series of reactions, the borazine ring is newly introduced into the first layer, and the first layer is changed (or modified) into a second layer having the borazine ring skeleton and containing Si, B, C, and N, i.e., a SiBCN layer having the borazine ring skeleton (hereinafter, which may also be simply referred to as a SiBCN layer). The second layer becomes a layer having a thickness, for example, from less than one atomic layer to several atomic layers. The SiBCN layer including the borazine ring skeleton may also be referred to as a layer containing Si, C, and having the borazine ring skeleton.

As the borazine ring is newly introduced into the first layer, the B component constituting the borazine ring is newly introduced into the first layer. Further, the N component constituting the borazine ring and the C component contained in the ligand of the TMB are newly introduced into the first layer.

Further, as described above, the C component contained in the C₃H₆ gas as well as the C component contained in the TMB gas is newly introduced into the first layer. Therefore, the second layer becomes a layer having a large amount of the C component, i.e., a C-rich layer, as compared to a layer obtained by modifying the first layer without supplying the C₃H₆ gas to the wafer 200 (i.e., a layer obtained by supplying only the TMB gas to the wafer 200 to modify the first layer).

In forming the second layer, Cl in the first layer and H in the TMB gas or the C₃H₆ gas forms, for example, gaseous substances such as a chlorine (Cl₂) gas, a hydrogen (H₂) gas, and a hydrogen chloride (HCl) gas in the course of the modification reaction of the first layer by the TMB gas and the C₃H₆ gas, and is exhausted from the process chamber 201 through the exhaust pipe 231. As such, impurities in the first layer such as Cl are separated from the first layer by being extracted or desorbed from the first layer. Thus, the second layer becomes a layer having a smaller amount of impurities such as Cl than the first layer.

Further, when forming the second layer, by maintaining the borazine ring skeleton constituting the borazine ring in the TMB without being broken, a central space of the borazine ring can be maintained, and thereby it becomes possible to form the SiBCN layer having a porous shape.

### (Residual Gas Removal)

After the second layer is formed, the valve 243c of the third gas supply pipe 232c and the valve 243i of the fifth gas supply pipe 232i are closed to stop the supply of the TMB gas and the C₃H₆ gas. Here, the interior of the process chamber 201 is vacuum-exhausted by the vacuum pump 246 while the APC valve 244 of the exhaust pipe 231 is in an open state, and the residual gas, which has not reacted or remains after contributing to the formation of the second layer, or reaction byproduct remaining in the process chamber 201 is removed from the process chamber 201. In addition, the supply of the N₂ gas into the process chamber 201 is maintained while the valves 243e to 243h are in an open state. The N₂ gas serves as a purge gas, and the residual gas, which has not reacted or remains after contributing to the formation of the second layer, or reaction byproduct remaining in the process chamber 201 can be more effectively removed from the process chamber 201

In this case, the gas remaining in the process chamber 201 may not be completely removed, and the interior of the process chamber 201 may not be completely purged. When the gas remaining in the process chamber 201 is minute, there is no adverse effect to be generated in Step 1 performed thereafter. Here, an amount of the N₂ gas supplied into the process chamber 201 need not be a large amount. For example, approximately the same amount of the N₂ gas as the volume of the reaction tube 203 (or the process chamber 201) may be supplied to perform the purge such that there is no adverse effect to be generated in Step 1. As described above, as the interior of the process chamber 201 is not completely purged, the purge time can be reduced to improve throughput. In addition, the consumption of the N₂ gas can be suppressed to a minimal necessity.

In addition to the TMB gas, for example, an organic precursor gas such as an n,n′,n″-triethylborazine (abbreviation: TEB) gas, an n,n′,n″-tri-n-propylborazine (abbreviation: TPB) gas, an n,n′,n″-triisopropylborazine (abbreviation: TIPB) gas, an n,n′,n″-tri-n-butylborazine (abbreviation: TBB) gas, an n,n′,n″-triisobutylborazine (abbreviation: TIBB) gas, or the like, may be used as the reaction gas including the organic borazine compound. For example, the TPB may be represented by the chemical structural formula shown in FIG. 12B in which R₁, R₃, and R₅ are H while R₂, R₄, and R₆ are a propyl group (—C₃H₇), or a chemical structural formula shown in FIG. 12D. In addition, the TMB is a borazine compound having a borazine ring skeleton and containing a methyl group as a ligand. The TEB is a borazine compound having a borazine ring skeleton and containing an ethyl group as a ligand. The TPB is a borazine compound having a borazine ring skeleton and containing a propyl group as a ligand. The TIPB is a borazine compound having a borazine ring skeleton and containing an isopropyl group as a ligand. The TBB is a borazine compound having a borazine ring skeleton and containing a butyl group as a ligand. The TIBB is borazine compound having a borazine ring skeleton and containing an isobutyl group as a ligand.

In addition to the propylene (C₃H₆) gas, a hydrocarbon-based gas such as an acetylene (C₂H₂) gas or an ethylene (C₂H₄) gas, that is, a carbon-containing gas not containing N may be used as the carbon-containing gas. By using the hydrocarbon-based gas, which contains C atoms but does not contain N atoms in its composition formula, as the carbon-containing gas, it is possible to suppress the N component from the carbon-containing gas from being added into the first layer, ultimately, into the second layer, when the carbon-containing gas is supplied to the wafer 200 in Step 3. That is, the N component can be added into the second layer only with the TMB gas as a nitrogen source. Consequently, it is possible to increase the C concentration while suppressing the increase of the N concentration in the SiBCN film having a borazine ring skeleton, which is formed in a later-described process that is performed a predetermined number of times.

As described above, the composition ratio of the SiBCN film can be appropriately controlled by appropriately selecting the gas species (component or composition) of the reaction gas or the gas species (component or composition) of the carbon-containing gas, respectively.

In addition, in order to further increase the C concentration in the SiBCN film, the pressure in the process chamber 201 when the TMB gas and the C₃H₆ gas are supplied in Step 3 may be set to be higher than the pressure in the process chamber 201 when the HCDS gas or the 3DMAS gas is supplied in Steps 1 and 2. The hydrocarbon-based gas such as the C₃H₆ gas is relatively less likely to be adsorbed onto the first layer, but by setting the pressure of the process chamber 201 as described above, it is possible to facilitate the adsorption of the C₃H₆ gas onto the first layer and, in addition, facilitate the reaction between the first layer and TMB gas. As a result, the C concentration in the second layer formed in Step 3, i.e., the C concentration in the SiBCN film can be further increased. On the contrary, in order to appropriately suppress the increment of the C concentration in the SiBCN film, the pressure in the process chamber 201 when the TMB gas and the C₃H₆ gas are supplied may be set to be lower than the pressure in the process chamber 201 when the HCDS gas or the 3DMAS gas is supplied. As such, it is possible to finely adjust the C concentration in the SiBCN film by appropriately controlling the pressure in the process chamber 201 when the TMB gas and the C₃H₆ gas are supplied.

In addition, the C concentration in the SiBCN film can also be finely adjusted by controlling supply conditions such as supply times and supply flow rates of the TMB gas and the C₃H₆ gas. For example, in Step 3, by extending the gas supply time of the TMB gas or the C₃H₆ gas or by increasing the supply flow rate of the TMB gas or the C₃H₆ gas, the C concentration in the SiBCN film can be further increased. Furthermore, for example, by increasing a ratio of the supply flow rate of the C₃H₆ gas to the supply flow rate of the TMB gas, that is to say, by setting the partial pressure of the C₃H₆ gas in the process chamber 201 to be greater than the partial pressure of the TMB gas in the process chamber 201, the C concentration in the SiBCN film can be increased. In addition, for example, in Step 3, by reducing the gas supply time of the TMB gas or the C₃H₆ gas or decreasing the supply flow rate of the TMB gas or the C₃H₆ gas, an increase in the C concentration in the SiBCN film can be appropriately controlled. Furthermore, for example, by reducing the ratio of the supply flow rate of the C₃H₆ gas to the supply flow rate of the TMB gas, that is to say, by setting the partial pressure of the C₃H₆ gas in the process chamber 201 to be smaller than the partial pressure of the TMB gas in the process chamber 201, an increase in the C concentration in the SiBCN film can be appropriately controlled. As such, it is possible to finely adjust the C concentration in the SiBCN film by controlling the supply conditions (a gas supply time, a supply flow rate, a partial pressure, a pressure in the process chamber 201, or the like) when supplying the TMB gas and the C₃H₆ gas.

In addition to the N₂ gas, a rare gas such as an Ar gas, a He gas, a Ne gas, a Xe gas, or the like, may be used as the inert gas.

### (Performing Predetermined Number of Times)

The above-described Steps 1 to 3 are set as one cycle, and the cycle may be performed one or more times (a predetermined number of times) to form a thin film having a borazine ring skeleton and containing silicon, boron, carbon, and nitrogen (hereinafter, referred to as a SiBCN film having a borazine ring skeleton, or simply a SiBCN film), which has a predetermined composition and a predetermined film thickness, on the wafer 200. In addition, it may be preferred that the above-described cycle be repeated a plurality number of times. That is, the thickness of the SiBCN layer formed by one cycle may be set to be smaller than a desired film thickness, and the above-described cycle may be repeated a plurality number of times until the desired film thickness is obtained. The SiBCN film having a borazine ring skeleton may also be referred to as a thin film containing silicon, carbon and a borazine ring skeleton.

In this case, ratios of individual components (i.e., Si component, B component, C component, and N component) in the SiBCN layer having a borazine ring skeleton, that is to say, a Si concentration, a B concentration, a C concentration, and a N concentration can be finely adjusted by controlling the process conditions such as the pressure of the process chamber 201 or the gas supply time in each step, thereby precisely controlling a composition ratio of the SiBCN film having a borazine ring skeleton. In addition, when the cycle is performed a plurality number of times, the phrase “a predetermined gas is supplied to the wafer 200” in each step after at least two cycles may mean that the predetermined gas is supplied to a layer formed on the wafer 200, i.e., an uppermost surface of the wafer 200, which is a laminated body. The phrase “a predetermined layer is formed on the wafer 200” may mean that the predetermined layer is formed on a layer formed on the wafer 200, i.e., an uppermost surface of the wafer 200, which is a laminated body. Also, the above-described matters are similar in respective modifications and other embodiments which will be described later.

### (Purge and Return to Atmospheric Pressure)

When the film-forming process of forming the SiBCN film having a borazine ring skeleton with a predetermined film thickness and a predetermined composition is performed, the valves 243e to 243h are opened, and the N₂ gas serving as an inert gas is supplied into the process chamber 201 from each of the inert gas supply pipes 232e to 232h and exhausted from the exhaust pipe 231. The N₂ gas serves as the purge gas, and thereby the interior of the process chamber 201 is purged with the inert gas so that the residual gas or the reaction byproducts remaining in the process chamber 201 are removed from the interior of the process chamber 201 (purge). Thereafter, an internal atmosphere in the process chamber 201 is substituted with the inert gas (inert gas substitution), and the pressure in the process chamber 201 returns to normal pressure (return to atmospheric pressure).

### (Boat Unloading and Wafer Discharging)

Thereafter, the seal cap 219 is lowered by the boat elevator 115 to open the lower end of the reaction tube 203, and the processed wafer 200 is unloaded from the lower end of the reaction tube 203 to the outside of the reaction tube 203 in a state where the wafer 200 is supported by the boat 217 (boat unloading). After that, the processed wafer 200 is discharged from the boat 217 (wafer discharge).

### (Second Sequence)

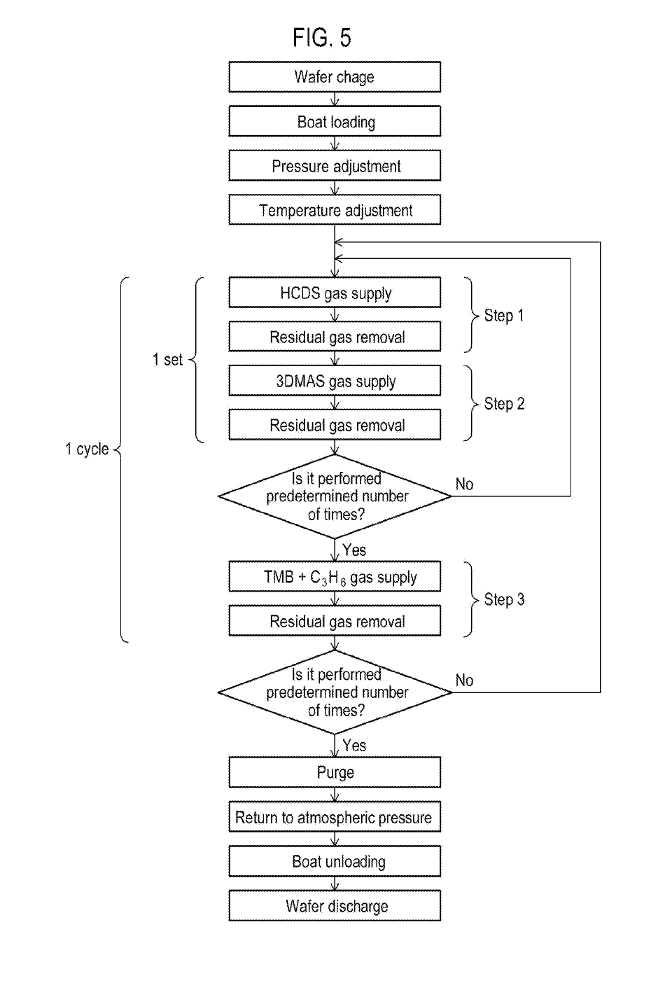

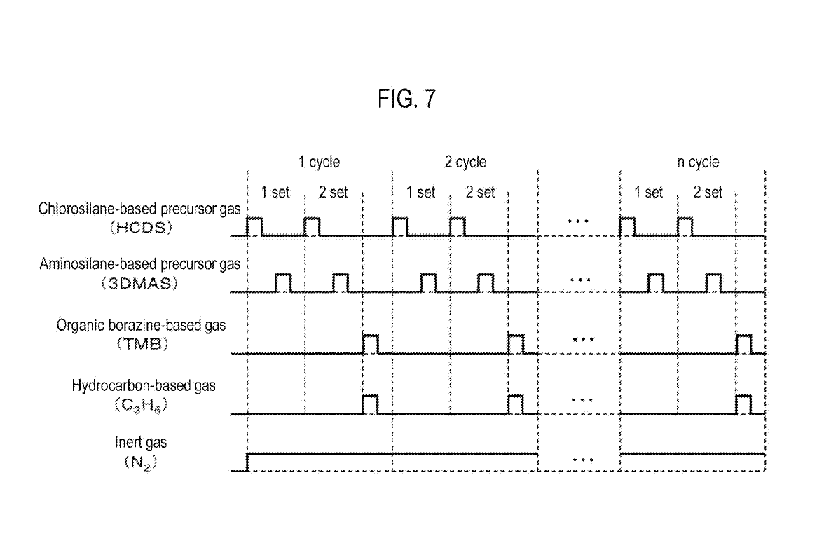

Next, a second sequence of the first embodiment will be described. FIG. 5 is a view showing a film-forming flow in the second sequence of the first embodiment of the present disclosure. FIG. 7 is a view showing gas supply timing in the second sequence of the first embodiment of the present disclosure.

In the second sequence of the first embodiment, a thin film containing silicon (Si), boron (B), carbon (C), and nitrogen (N) and having a borazine ring skeleton (a SiBCN film having a borazine ring skeleton) is formed on the wafer 200 by performing a cycle a first predetermined number of times. The cycle includes: forming a SiCN layer containing chlorine (Cl) as a first layer containing silicon (Si), chlorine (Cl), carbon (C) and nitrogen (N), by performing a set a second predetermined number of times (multiple times), the set including: supplying an HCDS gas as a first precursor gas containing silicon (Si) and a chloro group to the wafer 200; and supplying a 3DMAS gas as a second precursor gas containing silicon (Si) and an amino group to the wafer 200; and forming a SiBCN layer having the borazine ring skeleton as a second layer containing silicon (Si), boron (B), carbon (C), and nitrogen (N) and having the borazine ring skeleton, by supplying a TMB gas as a reaction gas, which contains an organic borazine compound, to the wafer 200 and thereby reacting the first layer with the organic borazine compound to modify the first layer under a condition in which the borazine ring skeleton in the organic borazine compound is maintained.

In addition, the C₃H₆ gas as a carbon-containing gas to the wafer 200 is supplied while the TMB gas is supplied. In addition, while the TMB gas is supplied, the C₃H₆ gas is supplied during the supply period of the TMB gas. That is, the TMB gas and the C₃H₆ gas are simultaneously supplied to the wafer 200 during the supply period of the TMB gas.

FIG. 7 shows an example of forming the SiBCN film having a borazine ring skeleton with a predetermined composition and a predetermined film thickness on the wafer 200. Such SiBCN film is formed by first performing a set including the above-described Steps 1 and 2 twice, then performing Step 3, and then setting these as one cycle and performing the cycle n times (n being a positive integer greater than zero). In addition, the only difference between second sequence and the first sequence is that in the second sequence, the above-described Steps 1 and 2 are set as one set and this set is repeated a plurality number of times, and then Step 3 is performed. Besides the above difference, the other steps may be performed similarly to the first sequence. In addition, the processing condition in the second sequence may be set similar to the processing condition of the above-described first sequence.

### (3) Effects According to the Present Embodiment

According to the present embodiment, one or more effects may be achieved as described below.

(a) According to the first and second sequences of the present embodiment, by performing a cycle including Steps 1 to 3 a predetermined number of times, it is possible to form a SiBCN film having a high resistance to HF and a low dielectric constant, as compared to a conventional SiCN film, SiOCN film, or the like, in a low temperature range on the wafer 200. Thus, under the low temperature range, a thin film may be formed to have both an improved resistance to HF and a reduced dielectric constant, which are in a trade-off relationship.

(b) According to the first and second sequences of the present embodiment, after forming the first layer on the wafer 200 by performing Steps 1 and 2, the TMB gas and the C₃H₆ gas are supplied in Step 3 to modify the first layer such that the second layer is formed. Accordingly, the composition of the SiBCN film can be easily controlled, and it is possible to form the SiBCN film having desired characteristics.

In particular, according to the first and second sequences of the present embodiment, three processes including a process of supplying the 3DMAS gas which is a first carbon source, a process of supplying the TMB gas which is a second carbon source, and a process of supplying the C₃H₆ gas which is a third carbon source are performed in one cycle. In other words, a film is formed by using three types of carbon sources (triple carbon sources) in one cycle. Thereby, it is possible to add the C component contained in the 3DMAS gas, the C component contained in the TMB gas, and the C component contained in the C₃H₆ gas, respectively, into the SiBCN film. Thereby, the C concentration in the SiBCN film can be further increased.

In addition, according to the first and second sequences of the present embodiment, by using the hydrocarbon-based gas (C₃H₆ gas), which contains C atoms but does not contain N atoms, as a carbon-containing gas, it is possible to prevent an N component from being added to the second layer from a carbon-containing gas, when a carbon-containing gas is supplied in Step 3. Thereby, it becomes easy to obtain high C concentration while preventing the N concentration in the SiBCN film from increasing.

Furthermore, by adjusting the B concentration and the C concentration of the SiBCN film, the resistance of the SiBCN film to HF or hot phosphoric acid can be controlled. For example, by increasing the B concentration and the C concentration of the SiBCN film, the resistance to HF can be higher than that of the SiN film, and by lowering the B concentration and the C concentration in the film, the resistance to HF can be lower than that of the SiN film. In addition, when the B concentration in the film is increased or decreased, a change in the resistance to the hot phosphoric acid may be different from a change in the resistance to HF, and when the C concentration in the film is increased or decreased, a change in the resistance to the hot phosphoric acid may be similar to a change in the resistance to HF. For example, by increasing the B concentration of the SiBCN film, the resistance to the hot phosphoric acid can be lower than that of the SiN film, and by lowering the B concentration in the SiBCN film, the resistance to the hot phosphoric acid can be higher than that of the SiN film. Further, for example, by increasing the C concentration in the SiBCN film, the resistance to the hot phosphoric acid can be higher than that of the SiN film, and by lowering the C concentration in the SiBCN film, the resistance to the hot phosphoric acid can be lower than that of the SiN film.

(c) According to the first and second sequences of the present embodiment, the gas containing the organic borazine compound (the TMB gas), which has high reducibility and high reactivity to an atom of a halogen element such as Cl, is used as the reaction gas. For this reason, in Step 3, the first layer and the reaction gas can be efficiently reacted with each other and the second layer can be formed more efficiently. Thereby, the productivity of the film-forming process of the SiBCN film can be improved.

In addition, according to the first and second sequences of the present embodiment, the process of supplying the C₃H₆ gas and the process of supplying the TMB gas are simultaneously performed, thereby it is possible to reduce the time for performing one cycle, as compared to the case where the above processes are separately performed. Accordingly, the decrease in the throughput when the SiBCN film is formed can be prevented, and it is possible to prevent the decrease in the productivity of the film-forming processing.

(d) According to the first and second sequences of the present embodiment, by using two precursor gases (silane sources) including the chlorosilane-based precursor gas and the aminosilane-based precursor gas, the SiBCN film with a good quality, which has superior characteristics as described above, can be formed. In addition, according to the experiments of the inventors, when a chlorosilane-based precursor gas group is used, it is difficult to deposit Si on the wafer 200 with a film-forming rate that satisfies productivity in the temperature range of 500 degrees C. or less. In addition, when an aminosilane-based precursor gas group is used, the Si may not be deposited on the wafer 200 in a temperature range of 500 degrees C. or less. However, according to the method of the present embodiment, the SiBCN film with a good quality, which has superior characteristics as described above, can be formed with a film-forming rate that satisfies productivity by a thermochemical reaction without using plasma.

In addition, even if the film-forming temperature is lowered, since the kinetic energy of a molecule is generally decreased, the reaction and desorption of the Cl containing in the chlorosilane-based precursor gas and the amine contained in the aminosilane-based precursor gas hardly occurs, and the ligands of the above remain on the surface of the wafer 200. Further, since these residual ligands become steric hindrance, the adsorption of the Si onto the surface of the wafer 200 is inhibited, and thereby the Si density is reduced and the film is degraded. However, under such condition where the reaction and desorption hardly proceeds, by appropriately reacting two silane sources, i.e., the chlorosilane-based precursor and the aminosilane-based precursor, those residual ligands may be desorbed. In addition, since the steric hindrance is resolved by the desorption of those residual ligands, it is possible that the Si is adsorbed into a site opened as a result, and the Si density can be increased. With the above-described process, it is understood that a film having a high Si density can be formed by a thermochemical reaction without using plasma even in a low temperature range of 500 degrees C. or less.

(e) According to the first and second sequences of the present embodiment, when the second layer is formed, the SiBCN film can be made to be a porous film, which further lowers the dielectric constant of the SiBCN film, by maintaining the borazine ring skeletons constituting the borazine rings in the organic borazine compound without being broken. As such, a low dielectric constant film (i.e., a low-k film) having very a low dielectric constant with a porous structure can be formed.

In addition, according to the first and second sequences of the present embodiment, when the second layer is formed, a central space of the borazine ring can be eliminated, for example, by increasing the wafer temperature or the internal pressure of the process chamber, compared with the processing conditions as described above, to break (not to maintain) at least a portion of the borazine ring skeletons constituting the borazine rings in the organic borazine compound. Thus, it is possible to vary a state (e.g., density) of the borazine ring skeletons in the SiBCN film, ultimately, a porous state (e.g., density) of the SiBCN film, so that the dielectric constant of the SiBCN film can be finely adjusted.

As described above, according to the first and second sequences of the present embodiment, the dielectric constant of the SiBCN film can be controlled, by changing the state of the borazine ring skeletons in the SiBCN film, in other words, by maintaining the borazine ring skeletons or breaking at least a portion thereof. Further, it is possible to control the film stress by varying the state of the borazine ring skeletons in the film.

(f) According to the first and second sequences of the present embodiment, by allowing the first layer and the TMB gas to react each other in Step 3, the impurity such as Cl or the like can be extracted or desorbed from the first layer. As a result, the impurity concentration in the SiBCN film can be reduced, and it is possible to further improve the resistance to HF of the SiBCN film.

(g) According to the second sequence of the present embodiment, Steps 1 and 2 are set as one set and this set is repeated a plurality number of times, then Step 3 is performed, and these are set as one cycle and this cycle is performed one or more times (a predetermined number of times). Thereby, the ratio of the Si component, the C component and the N component with respect to the B component in the SiBCN film may be appropriately controlled (in a richer direction), and the composition of the SiBCN film may be better controlled. In addition, by increasing the number of the set, the number of the layers of the first layer formed in one cycle may be increased by the number of the set, and therefore, it is possible to improve the cycle rate. Further, it is also possible to improve the film-forming rate as a result.

### (Modification)

In the first and second sequences shown in FIG. 4 to FIG. 7, an example is described in which the C₃H₆ gas is supplied in Step 3 where the TMB gas is supplied, but the present embodiment is not limited thereto. For example, the C₃H₆ gas may be supplied in Step 1 where the HCDS gas is supplied. In addition, the C₃H₆ gas may be supplied in Step 2 where the 3DMAS gas is supplied. Further, the C₃H₆ gas may be supplied in all of Step 1 to 3.

In these cases, the same effects as those of the above-described embodiment can be achieved. However, supplying the C₃H₆ gas in Step 3 may be preferred rather than supplying the C₃H₆ gas in Step 1 or Step 2, since it is possible to avoid the gas phase reaction between the HCDS gas and the C₃H₆ gas in the process chamber 201. In other words, it is possible to prevent particles in the process chamber 201 from being generated.

### Second Embodiment of the Present Disclosure

Hereinafter, a second embodiment of the present disclosure will be explained.

In the above-described first embodiment, a SiBCN film having a borazine ring skeleton is formed on a substrate by performing a cycle including Steps 1 to 3 a predetermined number of times. However, in the second embodiment, the SiBCN film having a borazine ring skeleton is formed on the substrate by performing a predetermined number of times a cycle including Step 4 of supplying a nitriding gas (an NH₃ gas) to the substrate, in addition to Steps 1 to 3. In a film-forming sequence of the second embodiment, a thin film containing a predetermined element, boron (B), carbon (C), and nitrogen (N) and having a borazine ring skeleton is formed on a substrate by performing a cycle a first predetermined number of times. The cycle includes: forming a first layer containing the predetermined element, a halogen group, carbon (C), and nitrogen (N) by performing a set a second predetermined number of times, the set including: supplying a first precursor gas containing the predetermined element and the halogen group to the substrate; and supplying a second precursor gas containing the predetermined element and an amino group to the substrate; forming a second layer containing the predetermined element, boron (B), carbon (C), and nitrogen (N) and having the borazine ring skeleton by supplying a reaction gas, which contains an organic borazine compound, to the substrate and thereby reacting the first layer with the organic borazine compound to modify the first layer under a condition in which the borazine ring skeleton in the organic borazine compound is maintained; and forming a third layer containing the predetermined element, boron (B), carbon (C), and nitrogen (N) and having the borazine ring skeleton by supplying a nitriding gas to the substrate and thereby nitriding the second layer to modify the second layer under a condition in which the borazine ring skeleton in the second layer is maintained.

In addition, a process of supplying a carbon-containing gas to the substrate may be performed in at least one of the process of supplying the first precursor gas, the process of supplying the second precursor gas, the process of supplying the reaction gas, and the process of supplying the nitriding gas. For example, the process of supplying the carbon-containing gas to the substrate may be performed during the process of supplying the reaction gas.

### (First Sequence)

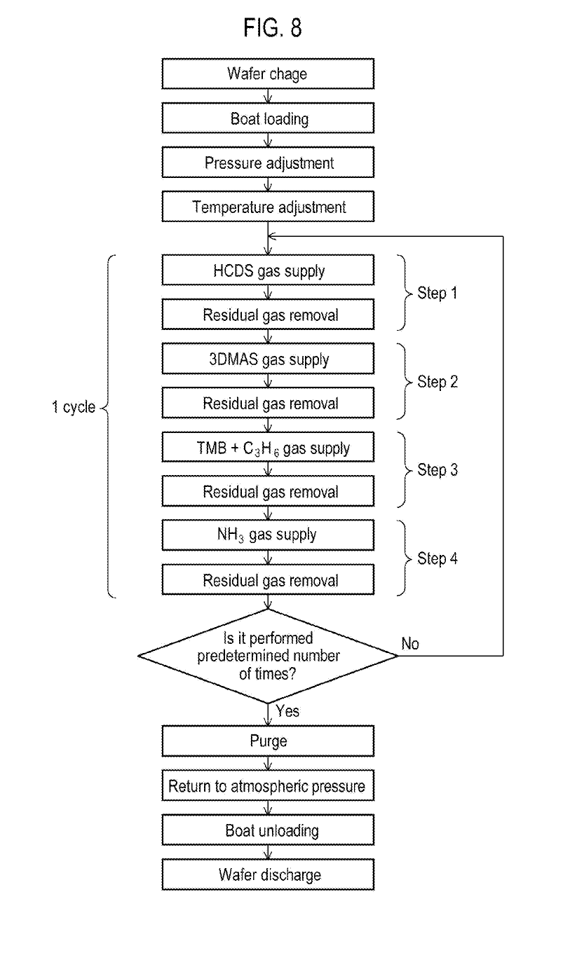

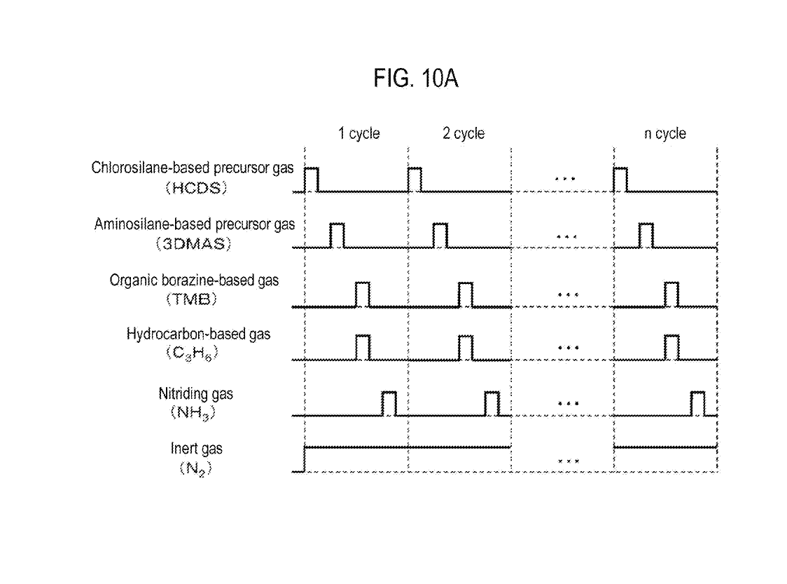

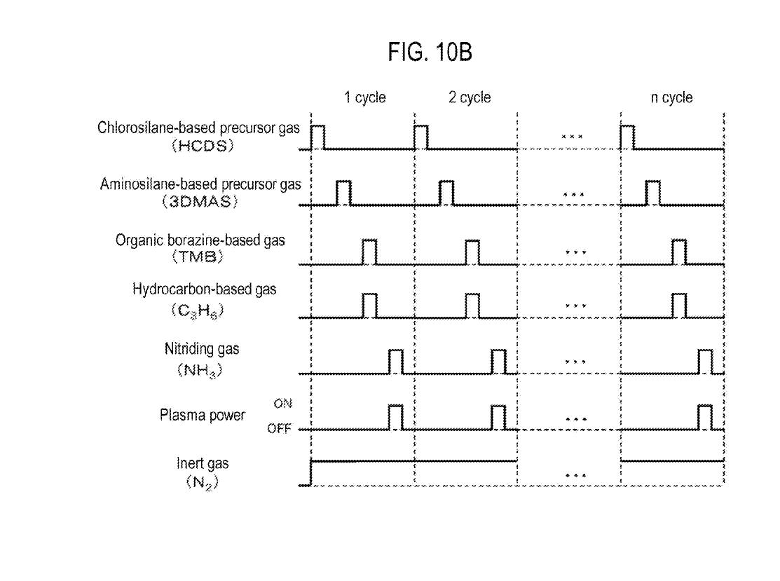

First of all, a first sequence of the second embodiment will be described. FIG. 8 is a view showing a film-forming flow in the first sequence of the second embodiment. FIGS. 10A and 10B are views showing timings of gas supply and plasma power (high-frequency power) supply in the first sequence of the second embodiment. FIG. 10A illustrates an example of a sequence of timings for supplying gases in the first sequence, in which a film is formed under non-plasma conditions. FIG. 7B illustrates an example of a sequence of timings for supplying gases and plasma power (e.g., high-frequency power) in the first sequence, in which a film is formed using plasma.

In the first sequence of the second embodiment, a thin film (a SiBCN film) containing silicon (Si), boron (B), carbon (C), and nitrogen (N) and having a borazine ring skeleton is formed on the wafer 200, by performing a cycle a first predetermined number of times, the cycle including: forming a SiCN layer containing chlorine (Cl) as a first layer containing silicon (Si), chlorine (Cl), carbon (C) and nitrogen (N), by performing a set a second predetermined number of times (one time), the set including: supplying an HCDS gas as a first precursor gas containing silicon (Si) and a chloro group to the wafer 200; and supplying a 3DMAS gas as a second precursor gas containing silicon (Si) and an amino group to the wafer 200; forming a SiBCN layer having the borazine ring skeleton as a second layer containing silicon (Si), boron (B), carbon (C), and nitrogen (N) and having the borazine ring skeleton, by supplying a TMB gas as a reaction gas, which contains an organic borazine compound, to the wafer 200 and thereby reacting the first layer with the organic borazine compound to modify the first layer under a condition in which the borazine ring skeleton in the organic borazine compound is maintained; and forming a SiBCN layer having the borazine ring skeleton as a third layer containing silicon (Si), boron (B), carbon (C), and nitrogen (N) and having the borazine ring skeleton by supplying an NH₃ gas as a nitriding gas to the wafer 200 and thereby nitriding the second layer to modify the second layer under a condition in which the borazine ring skeleton in the second layer is maintained.

In addition, a process of supplying a C₃H₆ gas as a carbon-containing gas to the wafer 200 is performed in the process of supplying the TMB gas, among the process of supplying the HCDS gas, the process of supplying the 3DMAS gas, the process of supplying the TMB gas and the process of supplying the NH₃ gas. In addition, in the process of supplying the TMB gas, the supply of the C₃H₆ gas is performed in the supply period of the TMB gas. That is, the TMB gas and the C₃H₆ gas are simultaneously supplied to the wafer 200.

The first sequence of the second embodiment has the same configurations as those of the first sequence of the first embodiment except that the former further includes Step 4 in addition to Steps 1 to 3. Hereinafter, Step 4 in the second embodiment is described.

### [Step 4]

### (NH₃ Gas Supply)

After Step 3 is completed and the residual gas in the process chamber 201 is removed, the valve 243d of the fourth gas supply pipe 232d is opened to cause the NH₃ gas to flow into the fourth gas supply pipe 232d. The NH₃ gas flowing through the fourth gas supply pipe 232d is flow rate-adjusted by the MFC 241d. The flow rate-adjusted NH₃ gas is supplied into the buffer chamber 237 through the gas supply holes 250d of the fourth nozzle 249d. Here, if high-frequency power is not applied between the first rod-shaped electrode 269 and the second rod-shaped electrode 270, the NH₃ gas supplied into the buffer chamber 237 is thermally activated (excited) to be supplied into the process chamber 201 through the gas supply holes 250e and exhausted through the exhaust pipe 231 (see FIG. 10A). In contrast, if high-frequency power is applied from the high-frequency power source 273 between the first rod-shaped electrode 269 and the second rod-shaped electrode 270 through the matcher 272, the NH₃ gas supplied into the buffer chamber 237 is plasma-excited and supplied into the process chamber 201 as active species through the gas supply holes 250e to be exhausted through the exhaust pipe 231 (see FIG. 10B). In this manner, the NH₃ gas activated by heat or plasma is supplied to the wafer 200. At the same time, the valve 243h is opened to cause the N₂ gas to flow into the fourth inert gas supply pipe 232h. The N₂ gas is supplied into the process chamber 201 together with the NH₃ gas, and exhausted through the exhaust pipe 231.

During this operation, in order to prevent infiltration of the NH₃ gas into the first nozzle 249a, the second nozzle 249b, and the third nozzle 249c, the valves 243e, 243f, and 243g are opened to cause the N₂ gas to flow into the first inert gas supply pipe 232e, the second inert gas supply pipe 232f, and the third inert gas supply pipe 232g. The N₂ gas is supplied into the process chamber 201 through the first gas supply pipe 232a, the second gas supply pipe 232b, the third gas supply pipe 232c, the first nozzle 249a, the second nozzle 249b, and the third nozzle 249c, and exhausted through the exhaust pipe 231.

When the NH₃ gas is heat-excited (not plasma-excited), the APC valve 244 is appropriately adjusted such that the internal pressure of the process chamber 201 falls within a range of, for example, 1 to 3,000 Pa. The internal pressure of the process chamber 201 is set to a relatively high pressure range so as to allow the NH₃ gas to be thermally activated under non-plasma conditions. In addition, when the NH₃ gas is thermally activated and supplied, it is possible to generate a relatively soft reaction so as to perform the nitriding more softly, which will be described later. Here, a partial pressure of the NH₃ gas in the process chamber 201 is set to fall within a range of, for example, 0.01 to 2,970 Pa. The supply flow rate of the NH₃ gas controlled by the MFC 241d is set to fall within a range of, for example, 100 to 10,000 sccm. The supply flow rate of the N₂ gas controlled by each of the MFCs 241e to 241h is set to fall within a range of, for example, 100 to 10,000 sccm. A time period for supplying the thermally activated NH₃ to the wafers 200, in other words, a gas supply time (i.e., an irradiation time), is set to fall within a range of, for example, 1 to 120 seconds, more specifically, 1 to 60 seconds. In this case, the temperature of the heater 207 is set such that the temperature of the wafers 200 falls within, for example, a range of 250 to 700 degrees C., more specifically, 300 to 650 degrees C., or further more specifically, 350 to 600 degrees C., in the same manner as described with respect to Steps 1 to 3.

When the NH₃ gas is plasma-excited and supplied as an active species, the APC valve 244 is appropriately adjusted such that the internal pressure of the process chamber 201 falls within a range of, for example, 1 to 100 Pa. Here, a partial pressure of the NH₃ gas in the process chamber 201 is set to fall within a range of, for example, 0.01 to 100 Pa. The supply flow rate of the NH₃ gas controlled by the MFC 241d is set to fall within a range of, for example, 100 to 10,000 sccm. The supply flow rate of the N₂ gas controlled by each of the MFCs 241e to 241h is set to fall within a range of, for example, 100 to 10,000 sccm. A time period for supplying the active species obtained by plasma-exciting the NH₃ gas to the wafers 200, in other words, a gas supply time (i.e., an irradiation time), is set to fall within a range of, for example, 1 to 120 seconds, more specifically, 1 to 60 seconds. In this case, the temperature of the heater 207 is set such that the temperature of the wafers 200 falls within, for example, a range of 250 to 700 degrees C., more specifically, 300 to 650 degrees C., or further more specifically, 350 to 600 degrees C., in the same manner as described with respect to Steps 1 to 3. The high-frequency power applied between the first rod-shaped electrode 269 and the second rod-shaped electrode 270 from the high-frequency power source 273 is set to fall within a range of, for example 50 to 1,000 W.

Here, the gas flowing into the process chamber 201 is the NH₃ gas which is thermally activated by increasing the internal pressure of the process chamber 201 or the active species obtained by plasma-exciting the NH₃ gas. At this time, none of the HCDS gas, the 3DMAS gas, the TMB gas, and the C₃H₆ gas is allowed to flow in the process chamber 201. Therefore, the NH₃ gas does not cause a gas phase reaction, and the activated NH₃ gas or the NH₃ gas that has become active species reacts with at least a portion of the second layer, which contains silicon (Si), boron (B), carbon (C), and nitrogen (N) and has a borazine ring skeleton, formed on the wafer 200 in Step 3. Thereby, the second layer is nitrided and modified into a third layer (SiBCN layer) containing silicon (Si), boron (B), carbon (C), and nitrogen (N) and having a borazine ring skeleton. The third layer is formed to have a thickness of, for example, less than one atomic layer to several atomic layers. In addition, the third layer has an N concentration higher than that of the second layer and a C concentration lower than that of the second layer.

In the process of forming the third layer, due to the nitriding gas, the second layer is modified by nitriding the second layer under the condition in which the borazine ring skeleton in the second layer is maintained. In this case, N is further added to the second layer by the nitriding of the second layer. In addition, the nitriding of the second layer allows at least a portion of C in the second layer to be separated (or extracted) from the second layer. In this case, the borazine ring skeleton constituting the borazine ring included in the second layer is maintained without being broken.

By supplying the NH₃ gas under the above-described conditions, the second layer and the NH₃ gas can be appropriately reacted while not destroying, but maintaining the borazine ring skeleton in the second layer, thereby causing the above-described reaction. In addition, it is believed that the most important factors (or conditions) for causing this reaction, with maintaining the borazine ring skeleton of the second layer, are the temperature of the wafers 200 and the internal pressure of the process chamber 201, especially the temperature of the wafers 200. Thus, it is possible to cause suitable reactions by appropriately controlling the factors.

In addition, as shown in FIG. 10A, when the thermally-activated NH₃ flows into the process chamber 201, the second layer can be thermally nitrided to be modified (or changed) into the third layer. In this case, at least a portion of the C component in the second layer is separated (or extracted) by energy of the activated NH₃ gas while a ratio of the N component in the second layer is increased, thereby finely adjusting the N concentration and the C concentration in the third layer. Specifically, the composition ratio of the third layer can be finely adjusted in a direction of increasing the N concentration and in a direction of reducing the C concentration. Further, the composition ratio of the third layer can be more precisely controlled by controlling the process conditions such as the internal pressure of the process chamber 201, the gas supply time, and the like.

Further, as shown in FIG. 10B, when the active species obtained by plasma-activating the NH₃ gas flows into the process chamber 201, the second layer can be plasma-nitrided to be modified (or changed) into the third layer. In this case, at least a portion of the C component in the second layer is separated (or extracted) by energy of the active species while a ratio of the N component in the second layer is increased, thereby finely adjusting the N concentration and the C concentration in the third layer. Specifically, the composition ratio of the third layer can be finely adjusted in a direction of increasing the N concentration and in a direction of reducing the C concentration. Further, the composition ratio of the third layer can be more precisely controlled by controlling the process conditions such as the internal pressure of the process chamber 201, the gas supply time, and the like.

Here, it is desirable that the nitriding reaction of the second layer is not saturated. For example, when the second layer having a thickness of a range from less than one atomic layer to several atomic layers is formed in Steps 1 to 3, a portion of the second layer may be nitrided. In this case, the nitriding may be performed in such a manner that the nitriding reaction of the second layer is unsaturated in order to prevent the entire second layer having the thickness of a range from less than one atomic layer to several atomic layers from being nitrided.

Although the unsaturation of the nitriding reaction of the second layer may be achieved under the above process conditions employed in Step 4, it can be more easily achieved by changing the process conditions of Step 4 to the following process conditions.

[When NH₃ gas is activated by heat]
Wafer temperature: 500 to 650 degrees C.
Internal pressure of process chamber: 133 to 2,666 Pa
Partial pressure of NH₃ Gas: 33 to 2,515 Pa
Supply flow rate of NH₃ Gas: 1,000 to 5,000 sccm
Supply flow fate of N₂ Gas: 300 to 3,000 sccm
Supply time of NH₃ Gas: 6 to 60 seconds
[When NH₃ Gas is activated by plasma]
Wafer temperature: 500 to 650 degrees C.
Internal pressure of process chamber: 33 to 80 Pa
Partial pressure of NH₃ gas: 17 to 75 Pa
Supply flow rate of NH₃ Gas: 1,000 to 5,000 sccm
Supply flow rate of N₂ Gas: 300 to 1,000 sccm
Supply time of NH₃ Gas: 6 to 60 seconds

### (Residual Gas Removal)

After the third layer is formed, the valve 243d of the fourth gas supply pipe 232d is closed to stop the supply of the NH₃ gas. At this time, while the APC valve 244 of the exhaust pipe 231 is in an open state, the interior of the process chamber 201 is vacuum-exhausted by the vacuum pump 246 to remove from the process chamber 201 the residual NH₃ gas, which has not reacted or remains after contributing to the formation of the third layer, or reaction byproducts remaining in the process chamber 201 (i.e., residual gas removal). In this operation, the supply of the N₂ gas into the process chamber 201 is maintained by keeping the valves 243e to 243h in an open state. The N₂ gas acts as a purge gas so as to enhance the effect of removing the residual NH₃ gas, which has not reacted or remains after contributing to the formation of the third layer, or reaction byproducts remaining in the process chamber 201, from the process chamber 201.

In this case, the gas remaining in the process chamber 201 may not be completely removed and the interior of the process chamber 201 may not be completely purged. When the gas remaining in the process chamber 201 is very small in amount, there is no adverse effect to be generated in following Step 1. Here, an amount of the N₂ gas supplied into the process chamber 201 need not be a large amount. For example, approximately the same amount of the N₂ gas as the volume of the reaction tube 203 (or the process chamber 201) may be supplied to perform the purge such that there is no adverse effect to be generated in Step 1. As described above, as the interior of the process chamber 201 is not completely purged, the purge time can be reduced and thus the throughput can be improved. In addition, the consumption of the N₂ gas can also be suppressed to a minimal necessity.

In addition to the NH₃ gas, a diazene (N₂H₂) gas, a hydrazine (N₂H₄) gas, a N₃H₈ gas, a gas containing the above compounds, or the like, may be used as the nitrogen containing gas. In addition to the N₂ gas, a rare gas such as an Ar gas, a He gas, a Ne gas, a Xe gas, or the like, may be used as the inert gas.

### (Performing Predetermined Number of Times)

The above-described Steps 1 to 4 are set as one cycle, and the cycle may be performed one or more times (a predetermined number of times) to form the SiBCN film having a borazine ring skeleton and containing a predetermined composition, which has a predetermined film thickness, on the wafer 200. In addition, it may be preferred to repeat the above-described cycle a plurality number of times. That is, a thickness of the SiBCN layer formed per cycle may be set to be smaller than a desired film thickness and the above cycle may be repeated a plurality number of times until the desired film thickness is obtained.

### (Second Sequence)

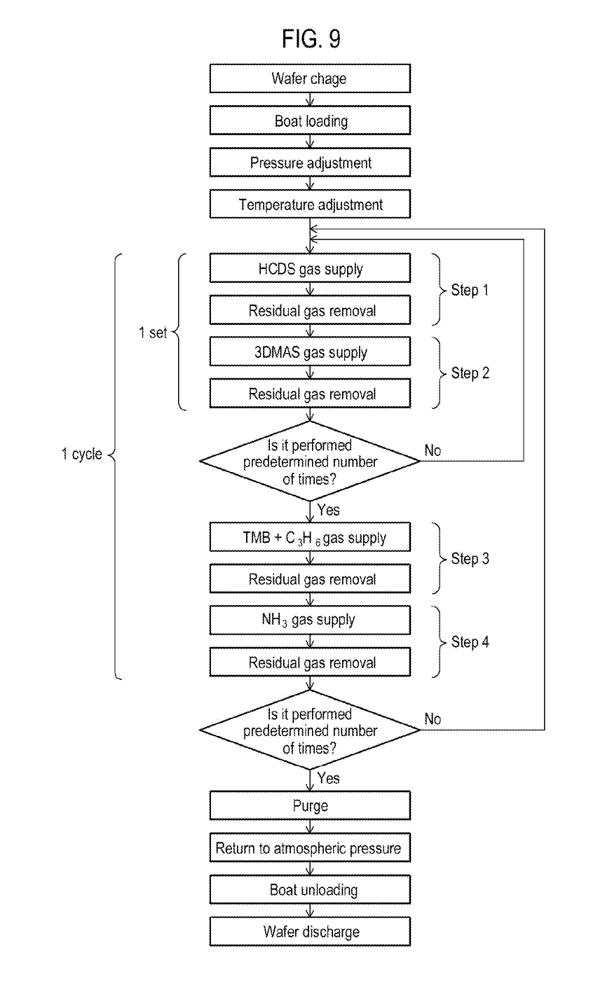

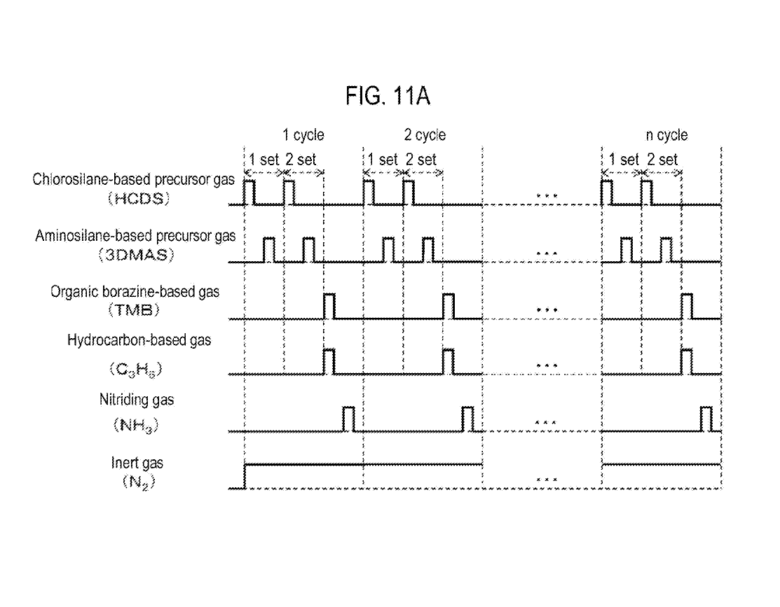

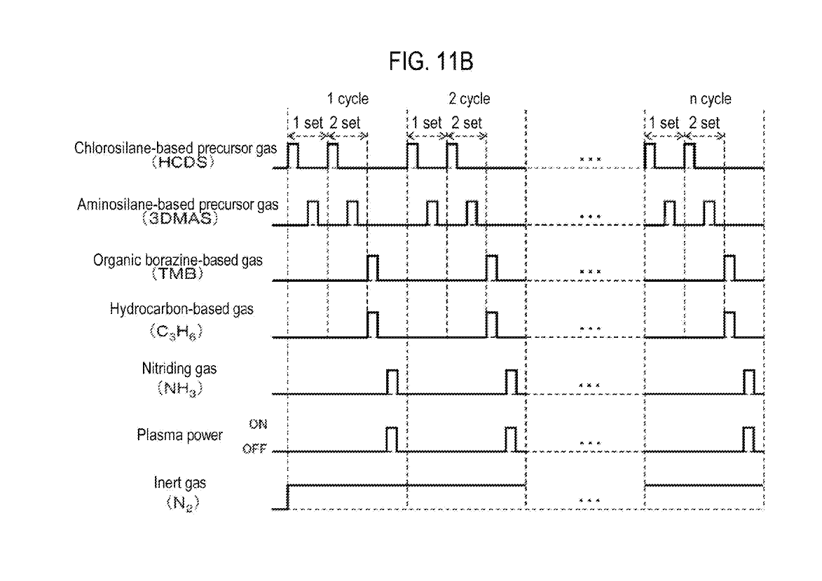

Next, a second sequence of the second embodiment will be described. FIG. 9 is a view showing a film-forming flow in the second sequence of the second embodiment of the present disclosure. FIG. 11A illustrates an example of a sequence of timings for supplying gases in the second sequence, in which a film is formed under non-plasma conditions, according to the second embodiment. FIG. 11B illustrates an example of a sequence of timing for supplying gases and plasma power in the second sequence, in which a film is formed using plasma, according to the second embodiment.

In the second sequence of the embodiment, a thin film (a SiBCN film) containing silicon (Si), boron (B), carbon (C), and nitrogen (N) and having a borazine ring skeleton is formed on the wafer 200, by performing a cycle a first predetermined number of times, the cycle including: forming a SiCN layer containing chlorine (Cl) as a first layer containing silicon (Si), chlorine (Cl), carbon (C) and nitrogen (N), by performing a set a second predetermined number of times (multiple of times), the set including: supplying an HCDS gas as a first precursor gas containing silicon (Si) and a chloro group to the wafer 200; and supplying a 3DMAS gas as a second precursor gas containing silicon (Si) and an amino group to the wafer 200; forming a SiBCN layer having the borazine ring skeleton as a second layer containing silicon (Si), boron (B), carbon (C), and nitrogen (N) and having the borazine ring skeleton, by supplying a TMB gas as a reaction gas, which contains an organic borazine compound, to the wafer 200 and thereby reacting the first layer with the organic borazine compound to modify the first layer under a condition in which the borazine ring skeleton in the organic borazine compound is maintained; and forming a SiBCN layer having the borazine ring skeleton as a third layer containing silicon (Si), boron (B), carbon (C), and nitrogen (N) and having the borazine ring skeleton by supplying an NH₃ gas as a nitriding gas to the wafer 200 and thereby nitriding the second layer to modify the second layer under a condition in which the borazine ring skeleton in the second layer is maintained.

Here, a process of supplying a C₃H₆ gas as a carbon-containing gas to the wafer 200 is performed in the process of supplying the TMB gas, among the process of supplying the HCDS gas, the process of supplying the 3DMAS gas, the process of supplying the TMB gas and the process of supplying the NH₃ gas. In addition, in the process of supplying the TMB gas, the supply of the C₃H₆ gas is performed in the supply period of the TMB gas. That is, the TMB gas and the C₃H₆ gas are simultaneously supplied to the wafer 200.

FIG. 11 shows an example of forming the SiBCN film having a borazine ring skeleton with a predetermined composition and a predetermined film thickness on the wafer 200, in which the above-described Steps 1 and 2 are set as one set, and a cycle, in which the set is performed twice and Steps 3 and 4 are then performed, is performed n times. The second sequence of the second embodiment has the same configurations as those of the first sequence of the second embodiment except that Steps 1 and 2 are set as one set, and after the set is performed a plurality number of times, Steps 3 and 4 are performed. The processing conditions in the second sequence may also be the same as those in the first film forming sequence described above.

### (Effects According to the Second Embodiment)

According to the first and second sequences of the second embodiment, the effects similar to those of the above-described first embodiment are obtained. In addition, according to the first and second sequences of the second embodiment, it is possible to finely adjust the composition ratio of the SiBCN film as described above by performing Step 4 where the NH₃ gas is supplied to the wafer 200.

### (Modification 1)

In the first and second sequences shown in FIG. 8 to FIG. 11, an example of supplying the C₃H₆ gas in Step 3, where the TMB gas is supplied, is described, however, the embodiment is not limited to the above example. For example, the C₃H₆ gas may be supplied in Step 1 where the HCDS gas is supplied. In addition, the C₃H₆ gas may be supplied in Step 2 where the 3DMAS gas is supplied. Further, the C₃H₆ gas may be supplied in Step 3 where the NH₃ gas is supplied. Furthermore, the C₃H₆ gas may be supplied in all of Steps 1 to 4.

In all the above cases, the effects similar to those of the above-described embodiment may be obtained. However, rather than supplying the C₃H₆ gas in Steps 1 and 2, it may be preferred to supply the C₃H₆ gas in Steps 3 and 4 because a gas phase reaction between the HCDS gas and the C₃H₆ gas, or a gas phase reaction between the 3DMAS gas and the C₃H₆ gas in the process chamber 201 can be prevented, that is, a particle generation in the process chamber 201 can be suppressed. In addition, rather than supplying the C₃H₆ gas in Step 4 where the NH₃ gas serving as a nitrogen source is supplied, it may be preferred to supply the C₃H₆ gas in Step 3 where the TMB gas serving as a carbon source is supplied because it may increase the controllability of the composition ratio of the SiBCN film.

### (Modification 2)

In the above-described Step 4, the nitriding gas is used to modify the second layer and adjust the N component and the C component of the second layer. That is, each component is adjusted in a direction of increasing the N component of the second layer, and in addition, in a direction of reducing the C component of the second layer. However, the embodiment is not limited to the above example. For example, a reaction gas containing N and C may be used instead of the nitriding gas. That is, in the above-described Step 4, the reaction gas containing N and C may be supplied to the wafer 200, and second layer and this reaction gas may be reacted to modify the second layer, thereby adjusting the N component and the C component of the second layer to form the third layer, under a condition in which the borazine ring skeleton in the second layer is maintained.

In the above case, the N and C contained in this reaction gas can be added to the second layer, and it is possible to respectively increase the N component and the C component of the second layer after the modification, i.e., the third layer. That is, the third layer becomes a SiBCN layer with increased (adjusted) N component and C component. In addition, as the reaction gas containing C and N is not plasma-excited, but thermally activated to be supplied, the desorption (extraction) effect of the C component from the second layer can be alleviated, and it becomes easy to control the C component ratio of the third layer. In other words, the C component ratio of the SiBCN film may be easily controlled in an increasing direction.

An amine-based gas may be used as the reaction gas containing C and N. Here, the amine-based gas may be a gas containing an amine group such as amine in a gaseous state, for example, a gas which is obtained by vaporizing amine in a liquid state under normal temperature and pressure, or amine which is in a gaseous state under normal temperature and pressure. The amine-based gas contains amine such as ethylamine, methylamine, propylamine, isopropylamine, butylamine, isobutylamine, and the like. As used herein, the term “amine” is a generic name of compounds in which a hydrogen atom in ammonia (NH₃) is substituted with a hydrocarbon group such as an alkyl group. As such, amine contains a hydrocarbon group such as an alkyl group as a ligand containing C atoms. Since the amine-based gas includes three elements of C, N, and H while not containing Si, it may be referred to as a Si-free gas. Further, since the amine-based gas does not contain Si and metal, it may be referred to as a Si-free and metal-free gas.

Examples of the amine-based gas may include an ethylamine-based gas obtained by vaporizing triethylamine ((C₂H₅)₃N, abbreviation: TEA), diethylamine ((C₂H₅)₂NH, abbreviation: DEA), monoethylamine (C₂H₅NH₂, abbreviation: MEA) and the like, a methylamine-based gas obtained by vaporizing trimethylamine ((CH₃)₃N, abbreviation: TMA), dimethylamine ((CH₃)₂NH, abbreviation: DMA), monomethylamine (CH₃NH₂, abbreviation: MMA) and the like, a propylamine-based gas obtained by vaporizing tripropylamine ((C₃H₇)₃N, abbreviation: TPA), dipropylamine ((C₃H₇)₂NH, abbreviation: DPA), monopropylamine (C₃H₇NH₂, abbreviation: MPA) and the like, an isopropyl amine-based gas obtained by vaporizing triisopropylamine ([(CH₃)₂CH]₃N, abbreviation: TIPA), diisopropylamine ([(CH₃)₂CH]₂NH, abbreviation: DIPA), monoisopropylamine ((CH₃)₂CHNH₂, abbreviation: MIPA) and the like, a butylamine-based gas obtained by vaporizing tributylamine (C₄H₉)₃N, abbreviation: TBA), dibutylamine ((C₄H₉)₂NH, abbreviation: DBA), monobutylamine (C₄H₉NH₂, abbreviation: MBA) and the like, and an isobutylamine-based gas obtained by vaporizing triisobutylamine ([(CH₃)₂CHCH₂]₃N, abbreviation: TIBA), diisobutylamine ([(CH₃)₂CHCH₂]₂NH, abbreviation: DIBA), monoisobutylamine ((CH₃)₂CHCH₂NH₂, abbreviation: MIBA) and the like. As such, at least one kind of gas, for example, (C₂H₅)ₓNH₃₋ₓ, (CH₃)ₓNH₃₋ₓ, (C₃H₇)ₓNH₃₋ₓ, [(CH₃)₂CH]ₓNH₃₋ₓ, (C₄H₉)ₓNH₃₋ₓ, and [(CH₃)₂CHCH₂]ₓNH₃₋ₓ (in the chemical formula, x is an integer from 1 to 3) may be used as the amine-based gas. In addition, when an amine in the liquid state under normal temperature and pressure, such as the TEA, is used, the amine in the liquid state is evaporated by an evaporation system such as an evaporator, a bubbler, or the like, and is supplied as the amine-based gas, i.e., a reaction gas containing C and N (TEA gas).

The amine-based gas serves as a nitrogen source and it serves as a carbon source as well. By using the amine-based gas as a reaction gas containing N and C, it is easier to control the ratio of one of the C component and the N component of the SiBCN film, in particular, in a direction of increasing the ratio of the C component.

Furthermore, examples of the gas containing N and C may include a gas containing an organic hydrazine compound, that is, an organic hydrazine-based gas, in addition to the amine-based gas. The organic hydrazine-based gas is a gas that has a hydrazine group, such as a gas obtained by vaporizing organic hydrazine, and contains C, N, and H. That is, the organic hydrazine-based gas is a gas containing no Si, and a gas containing no Si and metal. Examples of the organic hydrazine-based gas may include a methyl hydrazine-based gas obtained by vaporizing monomethylhydrazine ((CH₃)HN₂H₂, abbreviation: MMH), dimethylhydrazine ((CH₃)₂N₂H₂, abbreviation: DMH), trimethylhydrazine ((CH₃)₂N₂ (CH₃)H, abbreviation; TMH) and the like, and an ethyl hydrazine-based gas obtained by vaporizing ethylhydrazine ((C₂H₅)HN₂H₂, abbreviation: EH) and the like. When organic hydrazine in a liquid state under normal temperature and pressure such as MMH is used, the organic hydrazine in the liquid state may be vaporized by a vaporization system such as a vaporizer, a bubbler, or the like, and supplied as the organic hydrazine-based gas, i.e., the gas containing N and C (e.g., MMH gas). The gas containing an organic hydrazine compound may also be simply referred to as an organic hydrazine compound gas or an organic hydrazine gas.

### Additional Embodiments of the Present Disclosure

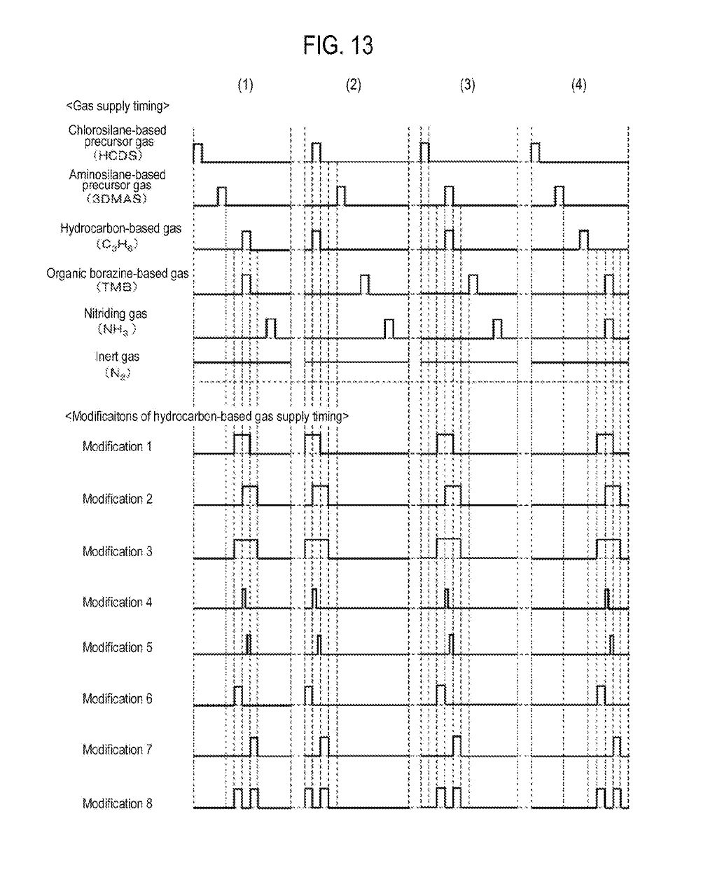

Hereinabove, various embodiments of the present disclosure have been specifically described, but the present disclosure is not limited to the above-described embodiments, and may be variously modified without departing from the spirit of the present disclosure. For example, in the film forming sequences of the embodiments as described above, an example is described in which the supply of the C₃H₆ gas is mainly performed simultaneously in a supply period of the TMB gas but not performed in a supply stop period of the TMB gas. However, the film forming sequence according to the present embodiment is not limited thereto, and may be modified as shown in FIG. 13. FIG. 13 is a view showing various modifications of the supply timing of the C₃H₆ gas, based on, for example, the film-forming sequence of FIG. 10A.

For example, when the process of supplying the C₃H₆ gas is performed in the process of supplying the TMB gas, as shown in Modifications 1 to 3 in column (1) of FIG. 13, the supply of the C₃H₆ gas may be performed in a period before starting the supply of the TMB gas, a period after stopping the supply of the TMB gas, or both periods, as well as in the supply period of the TMB gas. In addition, as shown in Modifications 4 and 5, the supply of the C₃H₆ gas may be performed only during a portion of the supply period of the TMB gas. Further, as shown in Modifications 6 to 8, the supply of the C₃H₆ gas may be performed, not in the supply period of the TMB gas, but in the period before starting the supply of the TMB gas, the period after stopping the supply of the TMB gas, or in both periods.

In addition, for example, when the process of supplying the C₃H₆ gas is performed in the process of supplying the HCDS gas, as shown in Modifications 1 to 3 in column (2) of FIG. 13, the supply of the C₃H₆ gas may be performed in a period before starting the supply of the HCDS gas, a period after stopping the supply of the HCDS gas, or both periods, as well as in the supply period of the HCDS gas. In addition, as shown in Modifications 4 and 5, the supply of the C₃H₆ gas may be performed only during a portion of the supply period of the HCDS gas. Further, as shown in Modifications 6 to 8, the supply of the C₃H₆ gas may be performed, not in the supply period of the HCDS gas, but in the period before starting the supply of the HCDS gas, the period after stopping the supply of the HCDS gas, or in both periods.

In addition, for example, when the process of supplying the C₃H₆ gas is performed in the process of supplying the 3DMAS gas, as shown in Modifications 1 to 3 in column (3) of FIG. 13, the supply of the C₃H₆ gas may be performed in a period before starting the supply of the 3DMAS gas, a period after stopping the supply of the 3DMAS gas, or both periods, as well as in the supply period of the 3DMAS gas. In addition, as shown in Modifications 4 and 5, the supply of the C₃H₆ gas may be performed only during a portion of the supply period of the 3DMAS gas. Further, as shown in Modifications 6 to 8, the supply of the C₃H₆ gas may be performed, not in the supply period of the 3DMAS gas, but in the period before starting the supply of the 3DMAS gas, the period after stopping the supply of the HCDS gas, or in both periods.

In addition, for example, when the process of supplying the C₃H₆ gas is performed in the process of supplying the NH₃ gas, as shown in Modifications 1 to 3 in column (4) of FIG. 13, the supply of the C₃H₆ gas may be performed in a period before starting the supply of the NH₃ gas, a period after stopping the supply of the NH₃ gas, or both periods, as well as in the supply period of the NH₃ gas. In addition, as shown in Modifications 4 and 5, the supply of the C₃H₆ gas may be performed only during a portion of the supply period of the NH₃ gas. Further, as shown in Modifications 6 to 8, the supply of the C₃H₆ gas may be performed, not in the supply period of the NH₃ gas, but in the period before starting the supply of the NH₃ gas, the period after stopping the supply of the NH₃ gas, or in both periods. Furthermore, the above similarly applies to the case where the process of supplying the C₃H₆ gas is performed in the process of supplying the TEA gas.

Thus, although the C₃H₆ gas may be supplied in the supply stop period of the TMB gas or the like, as well as the supply period of the TMB gas or the like, or may be supplied in the supply stop period of the TMB gas or the like rather than the supply period of the TMB gas or the like, the same effects as those of the above-described embodiments can be achieved.

Furthermore, in these modifications, it is possible to finely adjust the C concentration in the SiBCN film, by appropriately controlling the gas supply conditions (e.g., a supply time of gas, a supply flow rate, an internal pressure of the process chamber 201, a partial pressure of the C₃H₆ gas or the like) when the C₃H₆ gas is supplied in the supply period and/or the supply stop period of the TMB gas or the like. For example, if an internal pressure of the process chamber 201 (otherwise, a supply flow rate or a partial pressure of the C₃H₆ gas) when the C₃H₆ gas is supplied in the supply stop period of the TMB gas is set to be greater than an internal pressure of the process chamber 201 (otherwise, a supply flow rate or an internal pressure of the TMB gas) in the supply period of the TMB gas, it is possible to further increase the C concentration in the SiBCN film. Further, if the supply time of the C₃H₆ gas in the supply stop period of the TMB gas is set to be longer than the supply time of the TMB gas in the supply period of the TMB gas, it is possible to further increase the C concentration in the SiBCN film. Also, for example, if the internal pressure of the process chamber 201 (otherwise, a supply flow rate or a partial pressure of the C₃H₆ gas) when the C₃H₆ gas is supplied in the supply stop period of the TMB gas is set to be lower than an internal pressure of the process chamber 201 (otherwise, a supply flow rate or an internal pressure of the TMB gas) in the supply period of the TMB gas, it is possible to appropriately suppress the increase of the C concentration in the SiBCN film. Further, if the supply time of the C₃H₆ gas in the supply stop period of the TMB gas is set to be shorter than the supply time of the TMB gas in the supply period of the TMB gas, it is possible to appropriately suppress the increase of the C concentration in the SiBCN film.

In addition, according to these modifications, the C concentration in the SiBCN film can be increased without setting the pressure in the process chamber 201 in the supply period of the TMB gas to be excessively high, or setting the supply time of the TMB gas to be excessively long, or setting the supply flow rate of the TMB gas to be excessively large. In other words, if the supply conditions (e.g., a supply time of the gas, a supply flow rate, an internal pressure of the process chamber 201, a partial pressure of the C₃H₆ gas, and the like) when the C₃H₆ gas is supplied in the supply stop period of the TMB gas are appropriately controlled, while setting the supply conditions (e.g., a supply time of the gas, a supply flow rate, an internal pressure of the process chamber 201, a partial pressure of the TMB gas, and the like) in the supply period of the TMB gas, it is possible to increase the C concentration in the SiBCN film. Furthermore, since it is possible to reduce the consumption of relatively expensive TMB gas, the substrate processing costs can be reduced.

Further, for example, in the above-described embodiments, when the first layer is formed in each sequence, an example in which the chlorosilane-based precursor gas is supplied to the wafer 200, and then the aminosilane-based precursor gas is supplied has been described. However, the supply order of these precursor gases may be reversed. That is, the aminosilane-based precursor gas may be supplied, and then the chlorosilane-based precursor gas may be supplied. That is, one of the chlorosilane-based precursor gas and the aminosilane-based precursor gas may be first supplied, and then the other precursor gas may be supplied. As described above, the supply order of the precursor gases may be changed to vary the film quality of the thin film. In addition, for example, it is also possible to vary the film quality of the thin film to be formed, by changing the supply order of all the gases including the chlorosilane-based precursor gas and the aminosilane-based precursor gas, as well as the supply order of the chlorosilane-based precursor gas and the aminosilane-based precursor gas.

Further, for example, in the above-described embodiments, an example of using the chlorosilane-based precursor gas in forming the first layer in each sequence has been described, but a silane-based precursor gas with a halogen-based ligand other than a chloro group may be used instead of the chlorosilane-based precursor gas. For example, a fluorosilane-based precursor gas may be used instead of the chlorosilane-based precursor gas. Here, the fluorosilane-based precursor gas refers to a fluorosilane-based precursor in a gaseous state, for example, a gas which is obtained by vaporizing a fluorosilane-based precursor in a liquid state under normal temperature and pressure, a fluorosilane-based precursor which is in a gaseous state under normal temperature and normal pressure, and the like. In addition, the fluorosilane-based precursor refers to a silane-based precursor having a fluoro group as a halogen group, and also refers to a precursor containing at least silicon (Si) and fluorine (F). As such, the fluorosilane-based precursor may refer to a kind of halide. Further, examples of the fluorosilane-based precursor gas may include a silicon fluoride gas such as a tetrafluorosilane gas, i.e., a silicon tetrafluoride (SiF₄) gas, a hexafluorodisilane (Si₂F₆) gas, and the like. In this case, when the first layer is formed in each sequence, the fluorosilane-based precursor gas is supplied and then the aminosilane-based precursor gas is supplied to the wafer 200, or the aminosilane-based precursor gas is supplied and then the fluorosilane-based precursor gas is supplied. In this case, the first layer becomes a layer containing Si, F, C and N (i.e., a SiCN layer containing F).

Further, in the above-described embodiment, when the first layer is formed, an example in which the chlorosilane-based precursor gas is supplied to the wafer 200 and then the aminosilane-based precursor gas is supplied has been described. However, the chlorosilane-based precursor gas and the aminosilane-based precursor gas may be supplied simultaneously to the wafer 200 to generate a CVD reaction.

In other words, a thin film containing silicon (Si), boron (B), carbon (C), and nitrogen (N) and having a borazine ring skeleton (a SiBCN film having a borazine ring skeleton) may be formed on the wafer 200, by performing a cycle a predetermined number of times, the cycle including: forming a SiCN layer containing chlorine (Cl) as a first layer containing silicon (Si), chlorine (Cl), carbon (C) and nitrogen (N), by simultaneously supplying the chlorosilane-based precursor gas (HCDS gas) and the aminosilane-based precursor gas (3DMAS gas) to the wafer 200; and forming a SiBCN layer having the borazine ring skeleton as a second layer containing silicon (Si), boron (B), carbon (C), and nitrogen (N) and having the borazine ring skeleton, by supplying a reaction gas (TMB gas) containing an organic borazine compound to the wafer 200 and thereby reacting the first layer with the organic borazine compound to modify the first layer under a condition in which the borazine ring skeleton in the organic borazine compound is maintained.

In addition, a thin film containing silicon (Si), boron (B), carbon (C), and nitrogen (N) and having a borazine ring skeleton (a SiBCN film having a borazine ring skeleton) may be formed on the wafer 200, by performing a cycle a predetermined number of times, the cycle including: forming a SiCN layer containing chlorine (Cl) as a first layer containing silicon (Si), chlorine (Cl), carbon (C) and nitrogen (N), by simultaneously supplying the chlorosilane-based precursor gas (HCDS gas) and the aminosilane-based precursor gas (3DMAS gas) to the wafer 200; forming a SiBCN layer having the borazine ring skeleton as a second layer containing silicon (Si), boron (B), carbon (C), and nitrogen (N) and having the borazine ring skeleton, by supplying a reaction gas (TMB gas) containing an organic borazine compound to the wafer 200 and thereby reacting the first layer with the organic borazine compound to modify the first layer under a condition in which the borazine ring skeleton in the organic borazine compound is maintained; and forming a SiBCN layer having the borazine ring skeleton as a third layer containing silicon (Si), boron (B), carbon (C), and nitrogen (N) and having the borazine ring skeleton by supplying a nitriding gas (NH₃ gas) to the wafer 200 and thereby nitriding the second layer to modify the second layer under a condition in which the borazine ring skeleton in the second layer is maintained.

Also in the above cases, a process of supplying a carbon-containing gas (C₃H₆ gas) to the wafer 200 may be performed in at least one of the process of simultaneously supplying the chlorosilane-based precursor gas and the aminosilane-based precursor gas, the process of supplying the reaction gas, and the process of supplying the nitriding gas. For example, the process of supplying the carbon-containing gas to the wafer 200 may be performed in the process of supplying the reaction gas.

The processing conditions for the above cases may be set as the processing conditions similar to those for each sequence of the above-described embodiments. As such, the effects similar to those of the above-described embodiments are obtained even when the chlorosilane-based precursor gas and the aminosilane-based precursor gas are not sequentially supplied, but simultaneously supplied to the wafer 200. However, as in the above-described embodiments, the controllability of the film thickness may be increased by sequentially supplying each precursor gas, that is, by performing the supply of the chlorosilane-based precursor gas and the supply of the aminosilane-based precursor gas alternately with the purging of the interior of the process chamber 201 therebetween, because the chlorosilane-based precursor gas and the aminosilane-based precursor gas may be appropriately reacted with each other under a condition in which a surface reaction is dominant.

In addition, it is possible to provide a device forming technique having a small leak current and a good machinability by using the SiBCN film formed by the method of the above-described embodiments as a sidewall spacer.

Further, it is possible to provide a device forming technique having a good machinability by using the SiBCN film formed by the method of the above-described embodiments as an etching stopper layer.

Furthermore, according to the above-described embodiments, the SiBCN film having an ideal stoichiometric mixture ratio can be formed without using plasma even in a low temperature range. In addition, since the SiBCN film can be formed without using plasma, the above-described embodiments may be applied to a process having probability of plasma damage, for example, an SADP film of DPT.

In addition, in the above-described embodiments, an example in which the Si-based insulating film (SiBCN film) containing a semiconductor element Si is formed as a boron carbon nitride film has been described. However, the present disclosure may be applied to a case of forming a metal-based thin film containing a metal element, such as, a titanium boron carbon nitride film (TiBCN film), a zirconium boron carbon nitride film (ZrBCN film), a hafnium boron carbon nitride film (HfBCN film), a tantalum boron carbon nitride film (TaBCN film), an aluminum boron carbon nitride film (AlBCN film), a molybdenum boron carbon nitride film (MoBCN film), or the like.

In the above case, the film-forming may be performed with a sequence similar to that of the above-described embodiments, by using a precursor (first precursor) gas containing a metal element and a halogen group, instead of the chlorosilane-based precursor gas in the above-described embodiments, and using a precursor (second precursor) gas containing a metal element and an amino group, instead of the aminosilane-based precursor. For example, a precursor gas containing a metal element and a chloro group or a precursor gas containing a metal element and a fluoro group may be used as the first precursor gas.

That is, in the above case, a thin film containing a metal element, boron (B), carbon (C), and nitrogen (N) and having a borazine ring skeleton may be formed on the wafer 200, by performing a cycle a predetermined number of times, the cycle including: forming a first layer containing the metal element, a halogen group, carbon (C), and nitrogen (N) by performing a set a predetermined number of times (one or more times), the set including: supplying a first precursor gas containing the metal element and the halogen group to the wafer 200; and supplying a second precursor gas containing the metal element and an amino group to the wafer 200; and forming a second layer containing the metal element, boron (B), carbon (C), and nitrogen (N) and having the borazine ring skeleton by supplying a reaction gas, which contains an organic borazine compound, to the wafer 200 and thereby reacting the first layer with the organic borazine compound to modify the first layer under a condition in which the borazine ring skeleton in the organic borazine compound is maintained. Here, a process of supplying a carbon-containing gas to the wafer 200 may be performed in at least one of the process of supplying the first precursor gas, the process of supplying the second precursor gas, and the process of supplying the reaction gas. For example, the process of supplying the carbon-containing gas to the wafer 200 may be performed in the process of supplying the reaction gas.

Further, a thin film containing a metal element, boron (B), carbon (C), and nitrogen (N) and having a borazine ring skeleton may be formed on the wafer 200, by performing a cycle a predetermined number of times, the cycle including: forming a first layer containing the metal element, a halogen group, carbon (C), and nitrogen (N) by performing a set a predetermined number of times (one or more times), the set including: supplying a first precursor gas containing the metal element and the halogen group to the wafer 200; and supplying a second precursor gas containing the metal element and an amino group to the wafer 200; forming a second layer containing the metal element, boron (B), carbon (C), and nitrogen (N) and having the borazine ring skeleton by supplying a reaction gas, which contains an organic borazine compound, to the wafer 200 and thereby reacting the first layer with the organic borazine compound to modify the first layer under a condition in which the borazine ring skeleton in the organic borazine compound is maintained; and forming a third layer containing the metal element, boron (B), carbon (C), and nitrogen (N) and having the borazine ring skeleton by supplying a nitriding gas to the wafer 200 and thereby nitriding the second layer to modify the second layer under a condition in which the borazine ring skeleton in the second layer is maintained. Here, a process of supplying a carbon-containing gas to the wafer 200 may be performed in at least one of the process of supplying the first precursor gas, the process of supplying the second precursor gas, the process of supplying the reaction gas, and the process of supplying the nitriding gas. For example, the process of supplying the carbon-containing gas to the wafer 200 may be performed in the process of supplying the reaction gas.

For example, when a titanium (Ti)-based thin film is formed as the metal-based thin film, a precursor gas containing Ti and a chloro group, such as a titanium tetrachloride (TiCl₄) gas or the like, or a precursor gas containing Ti and a fluoro group, such as a titanium tetrafluoride (TiF₄) gas or the like, may be used as the first precursor gas. As the second precursor gas, a precursor gas containing Ti and an amino group, such as a tetrakis(ethylmethylamino)titanium (Ti[N(C₂H₅)(CH₃)]₄, abbreviation: TEMAT) gas, a tetrakis(dimethylamino)titanium (Ti[N(CH₃)₂]₄, abbreviation: TDMAT) gas, a tetrakis(diethylamino)titanium (Ti[N(C₂H₅)₂]₄, abbreviation: TDEAT) gas or the like may be used. As the reaction gas including the organic borazine compound, the nitriding gas and the carbon-containing gas, it is possible to use the same gases as those in the above-described embodiments. In addition, processing conditions in this example may be the same as those in the above-described embodiments.

In addition, for example, when a zirconium (Zr)-based thin film is formed as the metal-based thin film, a precursor gas containing Zr and a chloro group, such as a zirconium tetrachloride (ZrCl₄) gas or the like, or a precursor gas containing Zr and a fluoro group, such as a zirconium tetrafluoride (ZrF₄) gas or the like, may be used as the first precursor gas. As the second precursor gas, a precursor gas containing Zr and an amino group, such as a tetrakis(ethylmethylamino)zirconium (Zr[N(C₂H₅)(CH₃)]₄, abbreviation: TEMAZ) gas, a tetrakis(dimethylamino)zirconium (Zr[N(CH₃)₂]₄, abbreviation: TDMAZ) gas, or a tetrakis(diethylamino)zirconium (Zr[N(C₂H₅)₂]₄, abbreviation: TDEAZ) gas or the like may be used. As the reaction gas including the organic borazine compound, the nitriding gas and the carbon-containing gas, it is possible to use the same gases as those in the above-described embodiments. In addition, processing conditions in this example may be the same as those in the above-described embodiments.

In addition, for example, when a hafnium (HO-based thin film is formed as the metal-based thin film, a precursor gas containing Hf and a chloro group, such as a hafnium tetrachloride (HfCl₄) gas or the like, or a precursor gas containing Hf and a fluoro group, such as a hafnium tetrafluoride (HfF₄) or the like, may be used as the first precursor gas. As the second precursor gas, a precursor gas containing Hf and an amino group, such as a tetrakis(ethylmethylamino)hafnium (Hf[N(C₂H₅)(CH₃)]₄, abbreviation: TEMAH) gas, a tetrakis(dimethylamino)hafnium (Hf[N(CH₃)₂]₄, abbreviation: TDMAH) gas, a tetrakis(diethylamino)hafnium (Hf[N(C₂H₅)₂]₄, abbreviation: TDEAH) gas or the like may be used. As the reaction gas including an organic borazine compound, the nitriding gas and the carbon-containing gas, it is possible to use the same gases as those in the above-described embodiments. In addition, processing conditions in this example may be the same as those in the above-described embodiments.

In addition, a plurality of process recipes (e.g., programs describing process procedures and process conditions) used to form these various kinds of films may be individually prepared according to contents (e.g., kind, composition ratio, quality, thickness of films to be formed) of substrate processing. In addition, at the start of the substrate processing, an appropriate process recipe from the plurality of process recipes may be selected according to the substrate processing contents. Specifically, the plurality of process recipes individually prepared according to the substrate processing contents may be stored (or installed) in the memory device 121c of the substrate processing via a telecommunication line or a recording medium (e.g., the external memory device 123) storing the process recipes. In addition, at the start of the substrate processing, the CPU 121a of the substrate processing apparatus may select an appropriate process recipe from the plurality of process recipes stored in the memory device 121c, according to the substrate processing contents. This configuration allows a single substrate processing apparatus to form films having different composition ratios, qualities and thicknesses for general purposes and with high reproducibility. In addition, this configuration can reduce operation burden (a burden on input of process procedures and process conditions) of an operator, thereby avoiding a manipulation error and starting the substrate processing quickly.

The above-mentioned process recipes may be prepared, for example, by modifying existing process recipes already installed in the substrate processing apparatus, without being limited to newly prepared ones. When the process recipes are modified, the modified process recipes may be installed in the substrate processing apparatus via a telecommunication line or a recording medium storing the process recipes. In addition, the existing process recipes already installed in the substrate processing apparatus may be directly modified by operating the input/output device 122 of the substrate processing apparatus.

In addition, although the above embodiments illustrate that the batch type substrate processing apparatus to process a plurality of substrates at once is used to form the films, the present disclosure is not limited thereto but may be appropriately applied to film formation using a single wafer type substrate processing apparatus to process a single substrate or several substrates at once. In addition, although the above embodiments illustrate that the substrate processing apparatus including the hot wall type processing furnace is used to form the films, the present disclosure is not limited thereto but may be appropriately applied to a case where a substrate processing apparatus including a cold wall type processing furnace is used to form the films.

In addition, the above embodiments, modifications, and application examples may be used in proper combinations.

### <Additional Aspects of the Present Disclosure>

Hereinafter, some aspects of the present disclosure will be additionally stated.

### (Supplementary Note 1)

According to an aspect of the present disclosure, there is provided a method of manufacturing a semiconductor device, including forming a thin film containing a predetermined element, boron, carbon, and nitrogen and having a borazine ring skeleton on a substrate by performing a cycle a first predetermined number of times, the cycle including: supplying a first precursor gas containing the predetermined element and a halogen group to the substrate; supplying a second precursor gas containing the predetermined element and an amino group to the substrate; supplying a reaction gas including an organic borazine compound to the substrate; and supplying a carbon-containing gas to the substrate, wherein the cycle is performed under a condition in which the borazine ring skeleton in the organic borazine compound is maintained.

### (Supplementary Note 2)

In another aspect, supplying the carbon-containing gas is performed in a period during which the reaction gas is supplied.

### (Supplementary Note 3)

In another aspect, supplying the carbon-containing gas is performed in a period during which supply of the reaction gas is halted (e.g., a period before starting the supply of the reaction gas and/or a period after stopping the supply of the reaction gas).

### (Supplementary Note 4)

In another aspect, supplying the first precursor gas and supplying the second precursor gas are alternately performed a second predetermined number of times.

### (Supplementary Note 5)

In another aspect, supplying the first precursor gas and supplying the second precursor gas are simultaneously performed a third predetermined number of times.

### (Supplementary Note 6)

In another aspect, the carbon-containing gas includes a hydrocarbon-based gas.

### (Supplementary Note 7)

In another aspect, the cycle further includes supplying a nitriding gas to the substrate.

### (Supplementary Note 8)

In another aspect, the cycle includes: alternately or simultaneously performing supplying the first precursor gas and supplying the second precursor gas a second predetermined number of times, supplying the reaction gas, and supplying the nitriding gas.

### (Supplementary Note 9)

In another aspect, a thermally activated nitriding gas is supplied to the substrate while supplying the nitriding gas.

### (Supplementary Note 10)

In another aspect, a plasma-activated nitriding gas is supplied to the substrate while supplying the nitriding gas.

### (Supplementary Note 11)

In another aspect, the predetermined element includes silicon or a metal element, and the halogen element includes chlorine or fluorine.

### (Supplementary Note 12)

In another aspect, the cycle is performed the first predetermined number of times under a non-plasma condition.

### (Supplementary Note 13)

According to another aspect of the present disclosure, there is provided a method of processing a substrate, including forming a thin film containing a predetermined element, boron, carbon, and nitrogen and having a borazine ring skeleton on a substrate by performing a cycle a predetermined number of times, the cycle including: supplying a first precursor gas containing the predetermined element and a halogen group to the substrate; supplying a second precursor gas containing the predetermined element and an amino group to the substrate; supplying a reaction gas including an organic borazine compound to the substrate; and supplying a carbon-containing gas to the substrate, wherein the cycle is performed under a condition in which the borazine ring skeleton of the organic borazine compound is maintained.

### (Supplementary Note 14)

According to yet another aspect of the present disclosure, there is provided a substrate processing apparatus, including: a process chamber configured to accommodate a substrate; a first precursor gas supply system configured to supply a first precursor gas containing a predetermined element and a halogen group into the process chamber; a second precursor gas supply system configured to supply a second precursor gas containing the predetermined element and an amino group into the process chamber; a reaction gas supply system configured to supply a reaction gas including an organic borazine compound into the process chamber; a carbon-containing gas supply system configured to supply a carbon-containing gas into the process chamber; a heater configured to heat a substrate in the process chamber; a pressure adjusting part configured to adjust a pressure in the process chamber; and a control part configured to control the first precursor gas supply system, the second precursor gas supply system, the reaction gas supply system, the carbon-containing gas supply system, the heater, and the pressure adjusting part so as to perform a process of forming a thin film containing the predetermined element, boron, carbon, and nitrogen and having a borazine ring skeleton on the substrate, by performing a cycle a predetermined number of, the cycle including supplying the first precursor gas to the substrate in the process chamber, supplying the second precursor gas to the substrate in the process chamber, supplying the reaction gas to the substrate in the process chamber, and supplying the carbon-containing gas to the substrate in the process chamber, wherein the cycle is performed under a condition in which the borazine ring skeleton of an organic borazine compound is maintained.

### (Supplementary Note 15)

According to yet another aspect of the present disclosure, there is provided a program that causes a computer to perform a process of forming a thin film containing a predetermined element, boron, carbon, and nitrogen and having a borazine ring skeleton on a substrate in a process chamber of a substrate processing apparatus by performing a cycle a predetermined number of times, the cycle including: supplying a first precursor gas containing the predetermined element and a halogen group to the substrate in the process chamber; supplying a second precursor gas containing the predetermined element and an amino group to the substrate in the process chamber; supplying a reaction gas including an organic borazine compound to the substrate in the process chamber; and supplying a carbon-containing gas to the substrate in the process chamber, wherein the cycle is performed under a condition in which the borazine ring skeleton in the organic borazine compound is maintained.

### (Supplementary Note 16)

According to yet another aspect of the present disclosure, there is provided a non-transitory computer-readable recording medium storing a program that causes a computer to perform a process of forming a thin film containing a predetermined element, boron, carbon, and nitrogen and having a borazine ring skeleton on a substrate in a process chamber of a substrate processing apparatus by performing a cycle a predetermined number of times, the cycle including: supplying a first precursor gas containing the predetermined element and a halogen group to the substrate in the process chamber; supplying a second precursor gas containing the predetermined element and an amino group to the substrate in the process chamber; supplying a reaction gas including an organic borazine compound to the substrate in the process chamber; and supplying a carbon-containing gas to the substrate in the process chamber, wherein the cycle is performed under a condition in which the borazine ring skeleton in the organic borazine compound is maintained.

According to a method of manufacturing a semiconductor device, a substrate processing apparatus and a recording medium of the present disclosure, it is possible to form a thin film having a high resistance to HF and a low dielectric constant in a low temperature range, with a high productivity.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising forming a thin film containing a predetermined element, boron, carbon, and nitrogen and having a borazine ring skeleton on a substrate by performing a cycle a first predetermined number of times, the cycle comprising:
supplying a first precursor gas containing the predetermined element and a halogen group to the substrate;
supplying a second precursor gas containing the predetermined element and an amino group to the substrate;
supplying a reaction gas including an organic borazine compound to the substrate; and
supplying a carbon-containing gas to the substrate
wherein the cycle is performed under a condition in which the borazine ring skeleton in the organic borazine compound is maintained.

2. The method of claim 1, wherein supplying the carbon-containing gas is performed in a period during which the reaction gas is supplied.

3. The method of claim 1, wherein supplying the carbon-containing gas is performed in a period during which supply of the reaction gas is halted.

4. The method of claim 1, wherein supplying the first precursor gas and supplying the second precursor gas are alternately performed a second predetermined number of times.

5. The method of claim 1, wherein supplying the first precursor gas and supplying the second precursor gas are simultaneously performed a third predetermined number of times.

6. The method of claim 1, wherein the carbon-containing gas includes a hydrocarbon-based gas.

7. The method of claim 1, wherein the cycle further comprises supplying a nitriding gas to the substrate.

8. The method of claim 7, wherein the cycle comprises: alternately or simultaneously performing supplying the first precursor gas and supplying the second precursor gas a second predetermined number of times, supplying the reaction gas, and supplying the nitriding gas.

9. The method of claim 7, wherein a thermally activated nitriding gas is supplied to the substrate while supplying the nitriding gas.

10. The method of claim 7, wherein a plasma-activated nitriding gas is supplied to the substrate while supplying the nitriding gas.

11. The method of claim 1, wherein the predetermined element includes silicon or a metal element, and the halogen element includes chlorine or fluorine.

12. The method of claim 1, wherein the cycle is performed the first predetermined number of times under a non-plasma condition.

13. A substrate processing apparatus, comprising:
a process chamber configured to accommodate a substrate;
a first precursor gas supply system configured to supply a first precursor gas containing a predetermined element and a halogen group into the process chamber;
a second precursor gas supply system configured to supply a second precursor gas containing the predetermined element and an amino group into the process chamber;
a reaction gas supply system configured to supply a reaction gas including an organic borazine compound into the process chamber;
a carbon-containing gas supply system configured to supply a carbon-containing gas into the process chamber;
a heater configured to heat a substrate in the process chamber;
a pressure adjusting part configured to adjust a pressure in the process chamber; and
a control part configured to control the first precursor gas supply system, the second precursor gas supply system, the reaction gas supply system, the carbon-containing gas supply system, the heater, and the pressure adjusting part so as to perform a process of forming a thin film containing the predetermined element, boron, carbon, and nitrogen and having a borazine ring skeleton on the substrate, by performing a cycle a predetermined number of times, the cycle comprising: supplying the first precursor gas to the substrate in the process chamber; supplying the second precursor gas to the substrate in the process chamber; supplying the reaction gas to the substrate in the process chamber; and supplying the carbon-containing gas to the substrate in the process chamber, wherein the cycle is performed under a condition in which the borazine ring skeleton in the organic borazine compound is maintained.

14. A non-transitory computer-readable recording medium storing a program that causes a computer to perform a process of forming a thin film containing a predetermined element, boron, carbon, and nitrogen and having a borazine ring skeleton on a substrate in a process chamber by performing a cycle a predetermined number of times, the cycle comprising:
supplying a first precursor gas containing the predetermined element and a halogen group to the substrate in the process chamber;
supplying a second precursor gas containing the predetermined element and an amino group to the substrate in the process chamber;
supplying a reaction gas including an organic borazine compound to the substrate in the process chamber; and
supplying a carbon-containing gas to the substrate in the process chamber,
wherein the cycle is performed under a condition in which the borazine ring skeleton in the organic borazine compound is maintained.
